(19) United States
(12) Patent Application Publication
(10) Pub. No.: US 2025/0359050 A1
(43) Pub. Date: Nov. 20, 2025

(54) MEMORY DEVICE INCLUDING CONTOURED DRAIN-SELECT-LEVEL ISOLATION STRUCTURES AND METHODS FOR FORMING THE SAME

(71) Applicant: SANDISK TECHNOLOGIES LLC, ADDISON, TX (US)

(72) Inventors: Takashi KUDO, Yokkaichi (JP); Motoki MIZUTANI, Yokkaichi (JP); Yukihiro SAKOTSUBO, Yokkaichi (JP); Ryo NAKAMURA, Yokkaichi (JP); Kazuki ISOZUMI, Yokkaichi (JP); Hisaya SAKAI, Yokkaichi (JP)

(21) Appl. No.: 18/666,018

(22) Filed: May 16, 2024

(51) Int. Cl. H10B 43/27; H01L 23/00; H01L 25/00; H01L 25/065; H01L 25/18; H10B 80/00

(52) U.S. Cl. CPC H10B 43/27; H01L 24/08; H01L 24/80; H01L 25/0657; H01L 25/18; H01L 25/50; H10B 80/00; H01L 2224/08145; H01L 2224/80006; H01L 2224/80895; H01L 2224/80896; H01L 2924/1431; H01L 2924/14511

(57) ABSTRACT

A three-dimensional memory device includes an alternating stack of insulating layers and electrically conductive layers memory openings vertically extending through the alternating stack, memory opening fill structures located in the memory openings, and a drain-select-level isolation structure vertically extending through a subset of layers within the alternating stack and laterally extending generally along a first horizontal direction with lateral undulations along a second horizontal direction such that a first electrically conductive layer within the alternating stack is divided into a set of at least two first drain-select-level electrode strips. The drain-select-level isolation structure laterally protrudes into each memory opening fill structure in a first row and a second row and does not laterally protrude into the first drain-select-level electrode strips within gaps between neighboring pairs of memory opening fill structures.

### FIELD

The present disclosure relates generally to the field of semiconductor devices, and particularly to a memory device including contoured drain-select-level isolation structures and methods for forming the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device is provided, which comprises: an alternating stack of insulating layers and electrically conductive layers; memory openings vertically extending through the alternating stack; memory opening fill structures located in the memory openings, wherein each of the memory opening fill structures comprises a respective vertical semiconductor channel, a respective vertical stack of memory elements, and a respective drain region, wherein the memory opening fill structures are arranged in rows laterally extending along a first horizontal direction, and the rows are laterally spaced apart from each other along a second horizontal direction that is perpendicular to the first horizontal direction; and a drain-select-level isolation structure vertically extending through a subset of the electrically conductive layers within the alternating stack and laterally extending generally along the first horizontal direction with lateral undulations along the second horizontal direction such that a first electrically conductive layer within the alternating stack is divided into a set of at least two first drain-select-level electrode strips, wherein: the drain-select-level isolation structure is in contact with, and is located between, a first row of memory opening fill structures and a second row of memory opening fill structures; and the drain-select-level isolation structure laterally protrudes into each memory opening fill structure in the first row and the second row and does not laterally protrude into the first drain-select-level electrode strips within gaps between neighboring pairs of the memory opening fill structures that are laterally spaced along the first horizontal direction in the first row and the second row.

According to another aspect of the present disclosure, a method of forming a semiconductor structure is provided, which comprises: forming an alternating stack of insulating layers and spacer material layers over a substrate, wherein the spacer material layers are formed as, or are subsequently replaced with, electrically conductive layers; forming memory openings through the alternating stack; forming memory opening fill structures in the memory openings, wherein each of the memory opening fill structures comprises a respective memory film and a respective vertical semiconductor channel that is laterally surrounded by the respective memory film, wherein the memory opening fill structures are arranged in rows laterally extending along a first horizontal direction, and the rows are laterally spaced apart from each other along a second horizontal direction that is perpendicular to the first horizontal direction; forming a drain-select-level isolation trench through a subset of electrically conductive layers including a first electrically conductive layer such that the drain-select-level isolation trench divides the first electrically conductive layer into a pair of first drain-select-level electrode strips and includes volumes formed by removal of portions of a first row of memory opening fill structures and a second row of memory opening fill structures; and forming a drain-select-level isolation structure in the drain-select-level isolation trench, wherein the drain-select-level isolation structure laterally protrudes into each memory opening fill structure in the first row and the second row and does not laterally protrude into the first drain-select-level electrode strips within gaps between neighboring pairs of memory opening fill structures that are laterally spaced along the first horizontal direction in the first row and the second row.

### BRIEF DESCRIPTION OF THE DRAWINGS

FIG. 1 is a schematic vertical cross-sectional view of a first exemplary structure after formation of an alternating stack of insulating layers and sacrificial material layers over a carrier substrate according to a first embodiment of the present disclosure.

FIG. 2 is a schematic vertical cross-sectional view of the first exemplary structure after formation of stepped surfaces and a stepped dielectric material portion according to the first embodiment of the present disclosure.

FIG. 3A is a schematic vertical cross-sectional view of the first exemplary structure after formation of memory openings and support openings according to the first embodiment of the present disclosure. FIG. 3B is a top-down view of the first exemplary structure of FIG. 3A. The hinged vertical cross-sectional plane A-A′ is the cut plane of the vertical cross-sectional view of FIG. 3A.

FIG. 4 is a schematic vertical cross-sectional view of the first exemplary structure after formation of sacrificial opening fill structures according to the first embodiment of the present disclosure.

FIG. 5 is a vertical cross-sectional view of the first exemplary structure after formation of support pillar structures according to the first embodiment of the present disclosure.

FIG. 6 is a schematic vertical cross-sectional view of the first exemplary structure after removal of sacrificial memory opening fill structures according to the first embodiment of the present disclosure.

FIGS. 7A-7F are sequential vertical cross-sectional views of a memory opening during formation of a memory opening fill structure according to the first embodiments of the present disclosure.

FIG. 8A is a schematic vertical cross-sectional view of the first exemplary structure after formation of memory opening fill structures according to the first embodiment of the present disclosure. FIG. 8B is a top-down view of the first exemplary structure of FIG. 8A. The vertical plane A-A is the cut plane of the vertical cross-sectional view of FIG. 8A.

FIG. 9A is a vertical cross-sectional view of the first exemplary structure after formation of lateral isolation trenches according to the first embodiment of the present disclosure. FIG. 9B is a top-down view of the first exemplary structure of FIG. 9A. The vertical plane A-A is the cut plane of the vertical cross-sectional view of FIG. 9A.

FIG. 10 is a vertical cross-sectional view of the first exemplary structure after formation of laterally-extending cavities according to the first embodiment of the present disclosure.

FIG. 11 is a schematic vertical cross-sectional view of the first exemplary structure after formation of electrically conductive layers according to the first embodiment of the present disclosure.

FIG. 12 is a vertical cross-sectional view of the first exemplary structure after formation of lateral isolation trench fill structures, layer contact via structures, and drain contact via structures according to the first embodiment of the present disclosure.

FIG. 13A is a vertical cross-sectional view of the first exemplary structure after formation of in-process drain-select-level isolation trenches according to the first embodiment of the present disclosure. FIGS. 13B, 13C, and 13D are horizontal cross-sectional views of a region of the first exemplary structure along the horizontal planes B-B′, C-C′, and D-D′ in FIG. 13A, respectively. FIG. 13E is a top-down view of the first exemplary structure of FIG. 13A. The hinged vertical cross-sectional plane A-A′ in FIG. 13E is the cut plane of the vertical cross-sectional view of FIG. 13A.

FIG. 14 is a vertical cross-sectional view of the first exemplary structure after formation of a dielectric liner layer and an etch mask material layer according to the first embodiment of the present disclosure.

FIG. 15A is a vertical cross-sectional view of the first exemplary structure after formation of drain-select-level isolation trenches according to the first embodiment of the present disclosure. FIGS. 15B, 15C, and 15D are horizontal cross-sectional views of a region of the first exemplary structure along the horizontal planes B-B′, C-C′, and D-D′ in FIG. 15A, respectively.

FIG. 16A is a vertical cross-sectional view of the first exemplary structure after removal of the etch mask material layer according to the first embodiment of the present disclosure. FIG. 16B is a horizontal cross-sectional view of a region of the first exemplary structure along the horizontal planes B-B′ in FIG. 16A.

FIGS. 17A, 17B, and 17C are sequential horizontal cross-sectional views of a region of the first exemplary structure during various steps of an isotropic etch process according to the first embodiment of the present disclosure.

FIG. 18A is a vertical cross-sectional view of the first exemplary structure after lateral expansion of the drain-select-level isolation trenches according to the first embodiment of the present disclosure. FIGS. 18B, 18C, and 18D are horizontal cross-sectional views of a region of the first exemplary structure along the horizontal planes B-B′, C-C′, and D-D′ in FIG. 18A, respectively.

FIG. 19A is a vertical cross-sectional view of the first exemplary structure after formation of drain-select-level isolation structures according to the first embodiment of the present disclosure. FIGS. 19B, 19C, and 19D are horizontal cross-sectional views of a region of the first exemplary structure along the horizontal planes B-B′, C-C′, and D-D′ in FIG. 19A, respectively. FIG. 19E is a top-down view of the first exemplary structure of FIG. 19A. The hinged vertical cross-sectional plane A-A′ in FIG. 19E is the cut plane of the vertical cross-sectional view of FIG. 19A.

FIG. 20A is a vertical cross-sectional view of the first exemplary structure after formation of various contact via structures according to the first embodiment of the present disclosure. FIG. 20B is a top-down view of the first exemplary structure of FIG. 20A. The hinged vertical cross-sectional plane A-A′ in FIG. 20B is the cut plane of the vertical cross-sectional view of FIG. 20A.

FIG. 21 is a vertical cross-sectional view of the first exemplary structure after formation of a memory die according to the first embodiment of the present disclosure.

FIG. 22 is a vertical cross-sectional view of a logic die according to the first embodiment of the present disclosure.

FIG. 23 is a vertical cross-sectional view of the first exemplary structure after attaching the logic die to the memory die according to the first embodiment of the present disclosure.

FIG. 24 is a vertical cross-sectional view of the first exemplary structure after removal of the carrier substrate according to the first embodiment of the present disclosure.

FIG. 25A is a vertical cross-sectional view of the first exemplary structure after formation of a source layer and backside contact structures according to the first embodiment of the present disclosure. FIGS. 25B, 25C, and 25D are horizontal cross-sectional views of a region of the first exemplary structure along the horizontal planes B-B′, C-C′, and D-D′ in FIG. 25A, respectively.

FIG. 26A is a vertical cross-sectional view of a second exemplary structure after formation of drain-select-level isolation trenches according to a second embodiment of the present disclosure. FIGS. 26B, 26C, and 26D are horizontal cross-sectional views of a region of the second exemplary structure along the horizontal planes B-B′, C-C′, and D-D′ in FIG. 26A, respectively. FIG. 26E is a top-down view of the second exemplary structure of FIG. 26A. The hinged vertical cross-sectional plane A-A′ in FIG. 26E is the cut plane of the vertical cross-sectional view of FIG. 26A.

FIG. 27A is a vertical cross-sectional view of a second exemplary structure after formation of drain-select-level isolation structures according to the second embodiment of the present disclosure. FIGS. 27B, 27C, and 27D are horizontal cross-sectional views of a region of the second exemplary structure along the horizontal planes B-B′, C-C′, and D-D′ in FIG. 27A, respectively. FIG. 27E is a top-down view of the second exemplary structure of FIG. 27A. The hinged vertical cross-sectional plane A-A′ in FIG. 27E is the cut plane of the vertical cross-sectional view of FIG. 27A.

FIG. 28 is a vertical cross-sectional view of the second exemplary structure after bonding the memory die and a memory die, removal of the carrier substrate, and formation of a source layer and backside contact structures according to the second embodiment of the present disclosure.

### DETAILED DESCRIPTION

Without wishing to be bound by a particular theory, it is believe that three-dimensional NAND memory devices may experience a downward drift in the threshold voltage due to damage of an outer blocking dielectric during formation of drain-select-level isolation structures and/or due to contact between the outer blocking dielectric and the drain-select-level isolation structures, such there is no portion of a drain level select gate electrode remains between the outer blocking dielectric and the drain-select-level isolation structures. It is believed that this downshift arises from electron de-trapping from the charge storage layer into the outer blocking dielectric layer due to the damage and/or lack of a drain level select gate electrode between the outer blocking dielectric and the drain-select-level isolation structures (i.e., which leaves ungated portions of the outer blocking dielectric layer which accumulate the de-trapped electrons). This phenomenon decreases the reliability of the memory device performance. The embodiments of the present disclosure are directed to a memory device including contoured drain-select-level isolation structures and methods for forming the same, the various aspects of which are described below. Embodiments of the disclosure can be employed to form various structures including a multilevel memory structure, non-limiting examples of which include three-dimensional memory devices comprising a plurality of memory strings.

In some embodiments, the contoured drain-select-level isolation structures mitigate the downshift of the threshold voltage. The drain-select-level isolation structures are formed with a contoured horizontal cross-sectional profile such that the drain-select-level isolation structures laterally protrude into dielectric cores of memory opening fill structures (i.e., through the memory film and channel of the vertical NAND strings), while not having a lateral protrusion in gaps between neighboring memory opening fill structures. The outer blocking dielectric is completely removed in the ungated regions of the lateral protrusions, which is believed to reduce electron de-trapping into the outer blocking dielectric layer to mitigate the downshift of the threshold voltage. By stabilizing the threshold voltage of the NAND strings at the levels of the drain-select electrodes, more uniform device operating characteristics and enhanced reliability are provided.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

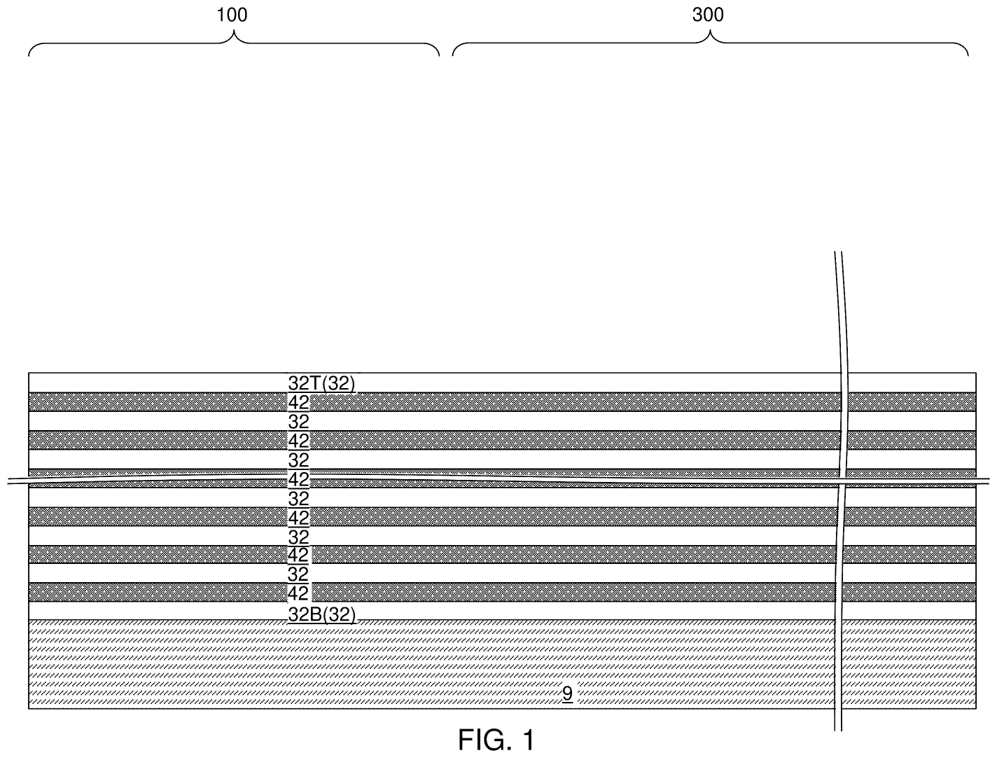

Referring to FIG. 1, a first exemplary structure according to the first embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective to the materials of insulating layers 32 and dielectric material portions to be subsequently formed.

An alternating stack of first material layers and second material layers can be formed over the carrier substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about one half of the thickness of other insulating layers 32.

The first exemplary structure comprises a memory array region 100 in which a three-dimensional array of memory elements is to be subsequently formed, and a contact region 300 in which layer contact via structures contacting word lines are to be subsequently formed.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

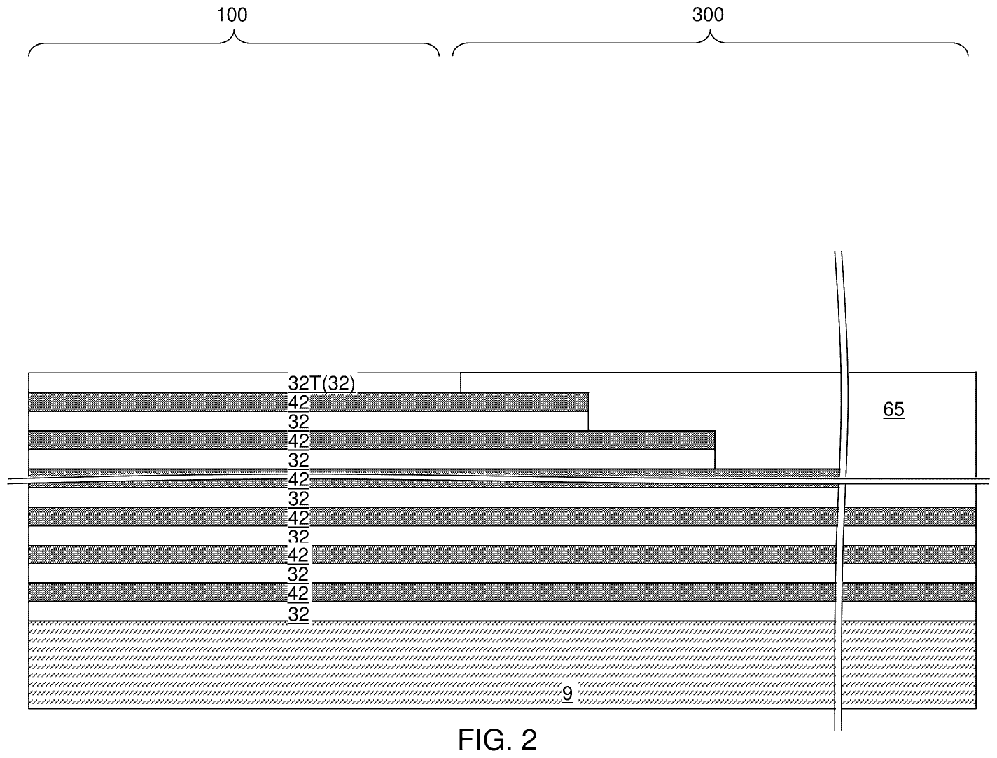

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the carrier substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

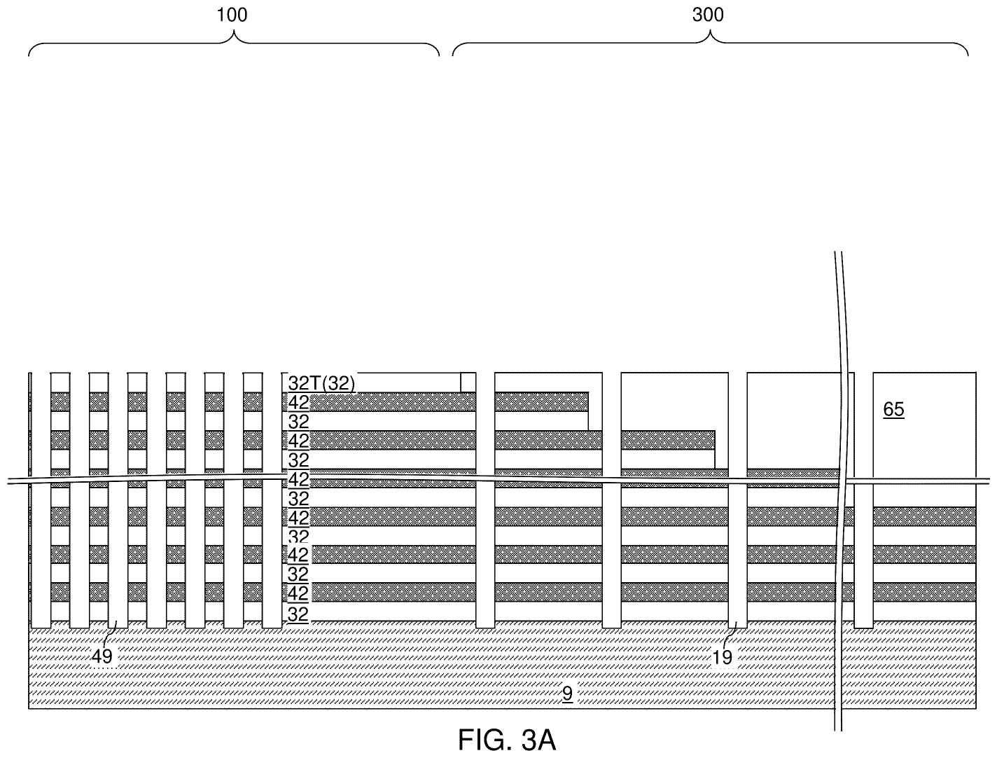

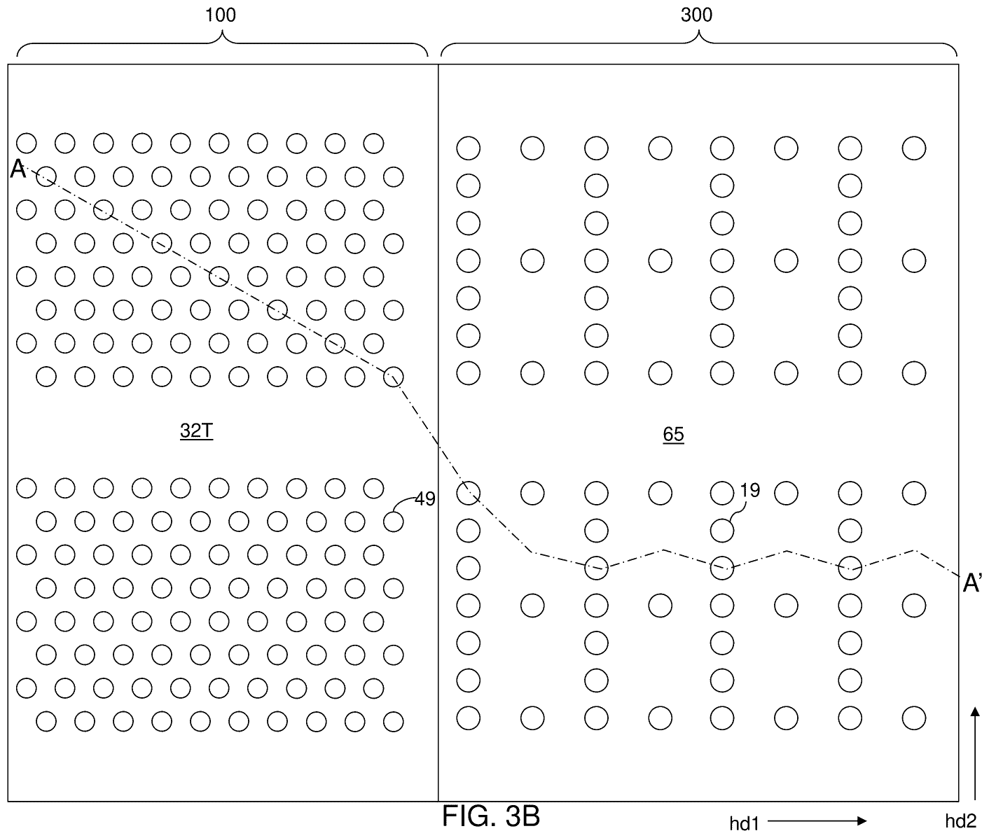

Referring to FIGS. 3A and 3B, an etch mask layer (such as a photoresist layer) can be formed over the alternating stack (32, 42), and can be lithographically patterned to form openings in the memory array region 100 and in the contact region 300. An anisotropic etch process can be performed to transfer the pattern of the openings in the etch mask layer through the stepped dielectric material portion 65 and the alternating stack (32, 42). Memory openings 49 are formed through the alternating stack (32, 42) in the memory array region 100. Support openings 19 can optionally be formed through the stepped dielectric material portion 65 and the alternating stack (32, 42) in the contact region 300.

Each of the memory openings 49 and the support openings 19 can vertically extend into the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser and greater diameters may be employed. The support openings 19 may have a diameter in a range from 60 nm to 400 nm, such as from 120 nm to 300 nm, although lesser and greater diameters may be employed.

Each cluster of memory openings 49 (which corresponds to an area of a memory block) may comprise a plurality of rows of memory openings 49. Each row of memory openings 49 may comprise a plurality of memory openings 49 that are arranged along the first horizontal direction hd1 (which may be a word line direction) with a uniform pitch. The rows of memory openings 49 may be laterally spaced from each other along the second horizontal direction hd2 (which may be a bit line direction), which may be perpendicular to the first horizontal direction hd1. In one embodiment, each cluster of memory openings 49 may be formed as a two-dimensional periodic array of memory openings 49.

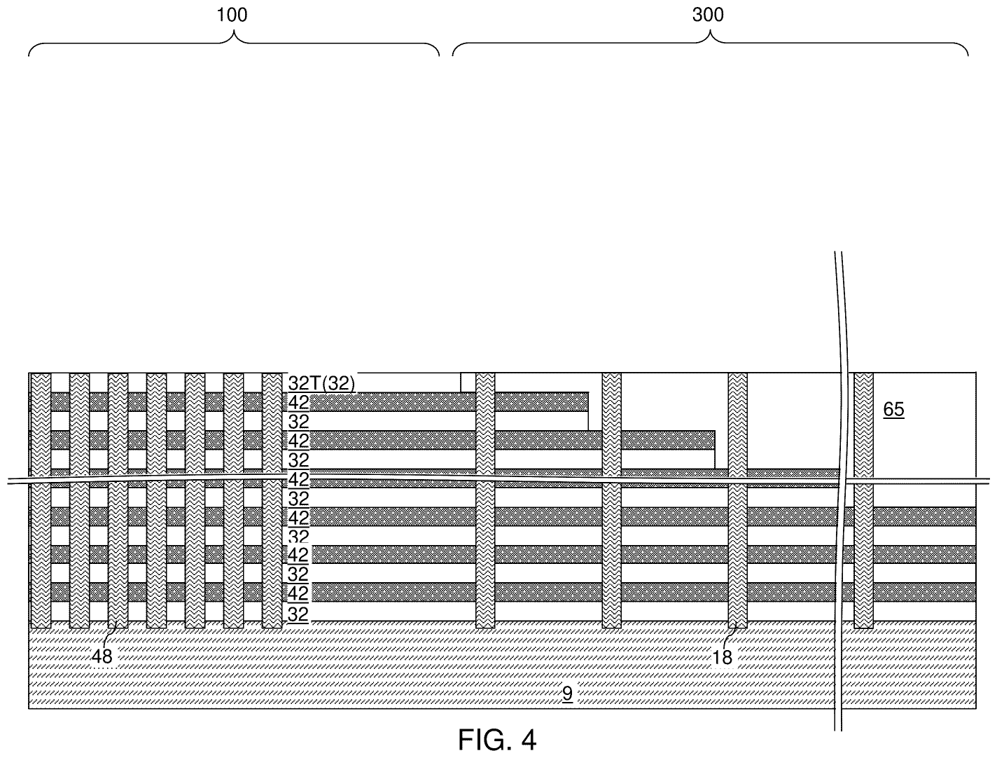

Referring to FIG. 4, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium), a polymer material, or a dielectric material (such as organosilicate glass or borosilicate glass). Excess portions of the sacrificial fill material may be removed from above the horizontal plane including the top surface of the topmost insulating layer 32T. Each remaining portion of the sacrificial fill material that fills a memory opening 49 constitutes a sacrificial memory opening fill structure 48. Each remaining portion of the sacrificial fill material that fills a support opening 19 constitutes a sacrificial support opening fill structure 18.

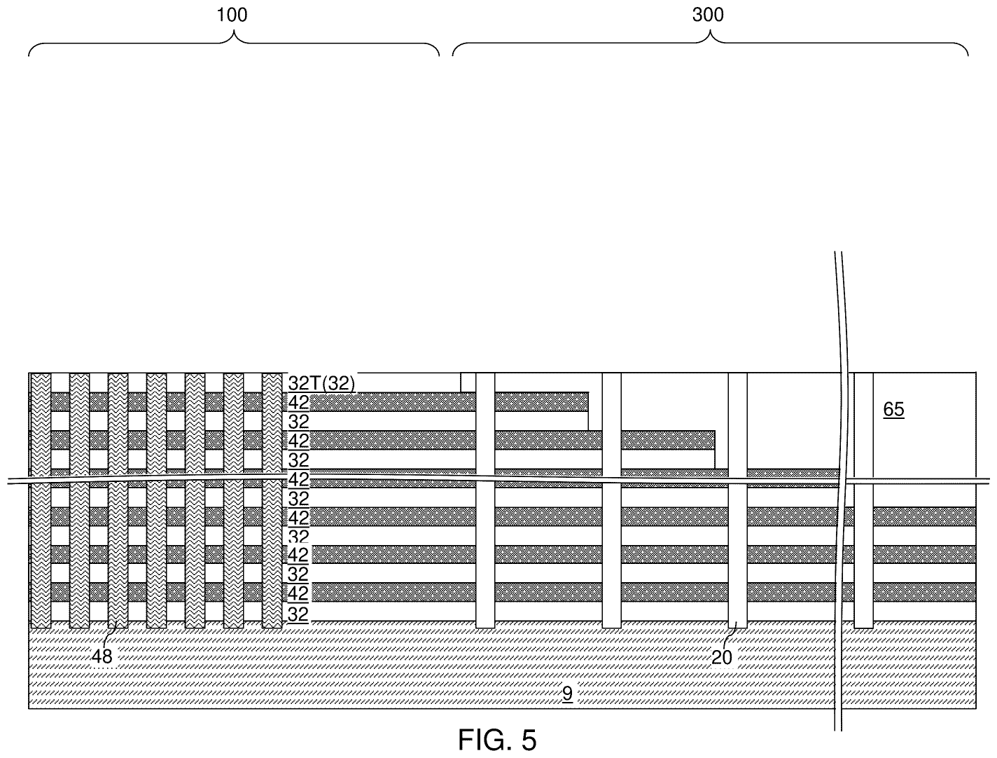

Referring to FIG. 5, a photoresist layer (not shown) can be applied over the first exemplary structure, and can be lithographically patterned to cover the sacrificial memory opening fill structures 48 in the memory array region 100 without covering the sacrificial support opening fill structures 18 in the contact region 300. The sacrificial support opening fill structures 18 are subsequently removed selective to the materials of the insulating layers 32, the sacrificial material layers 42, and the carrier substrate 9 by ashing or selective etching. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

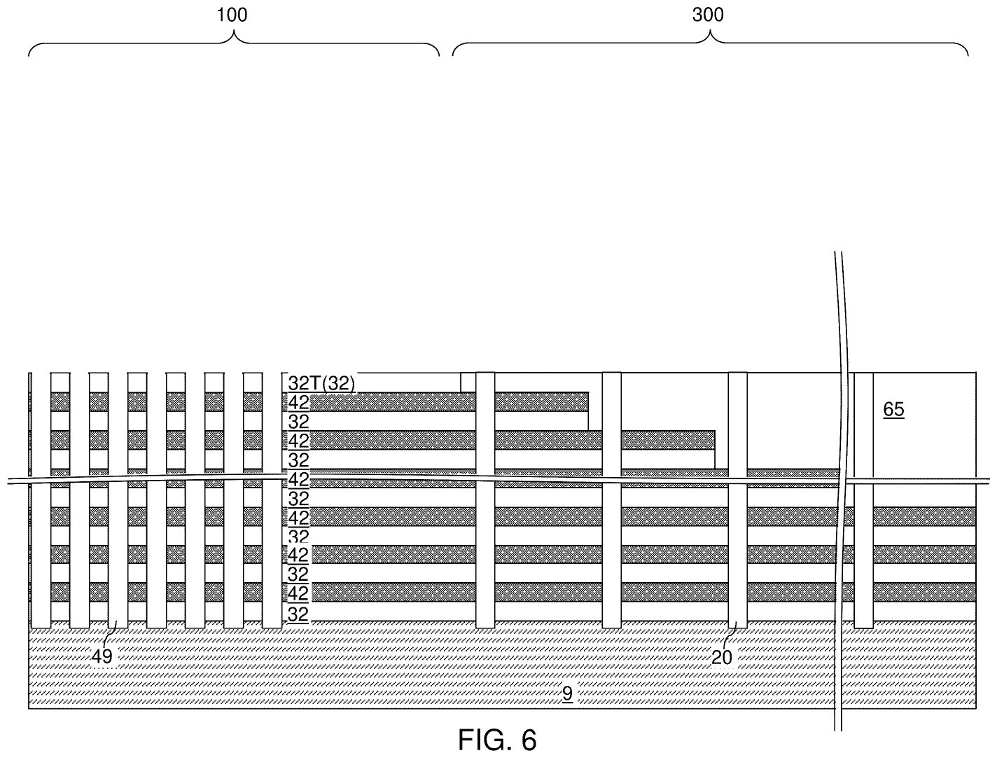

Referring to FIG. 6, sacrificial memory opening fill structures 48 are subsequently removed selective to the materials of the insulating layers 32, the sacrificial material layers 42, and the carrier substrate 9. Voids are formed in the volumes of the memory openings 49 from which the sacrificial memory opening fill structures 48 are removed.

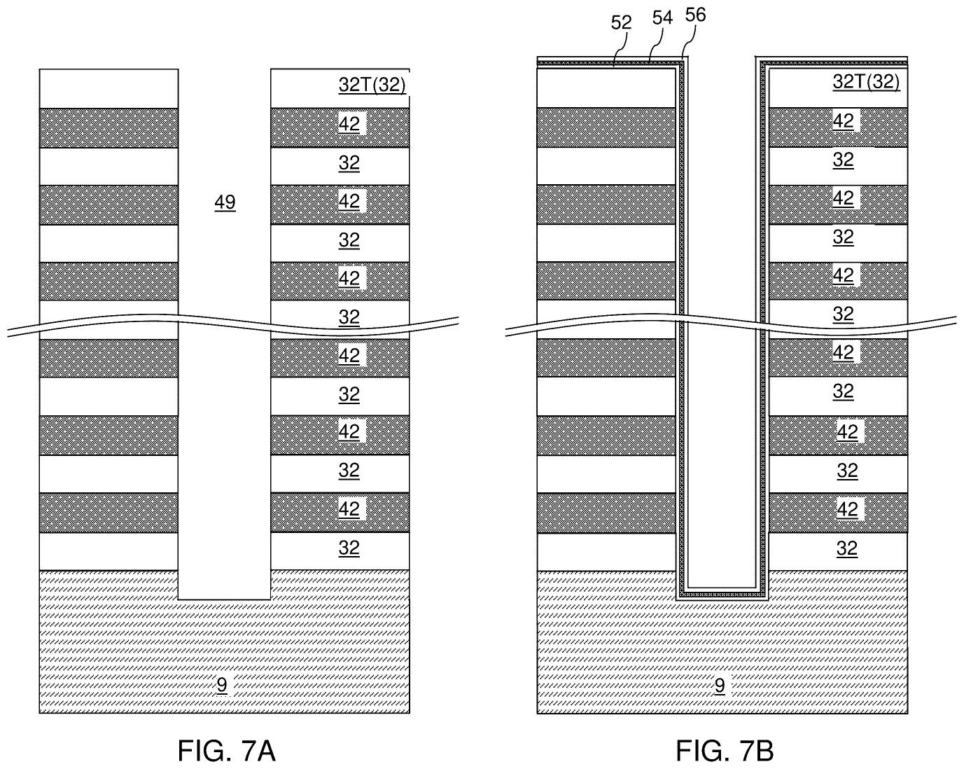

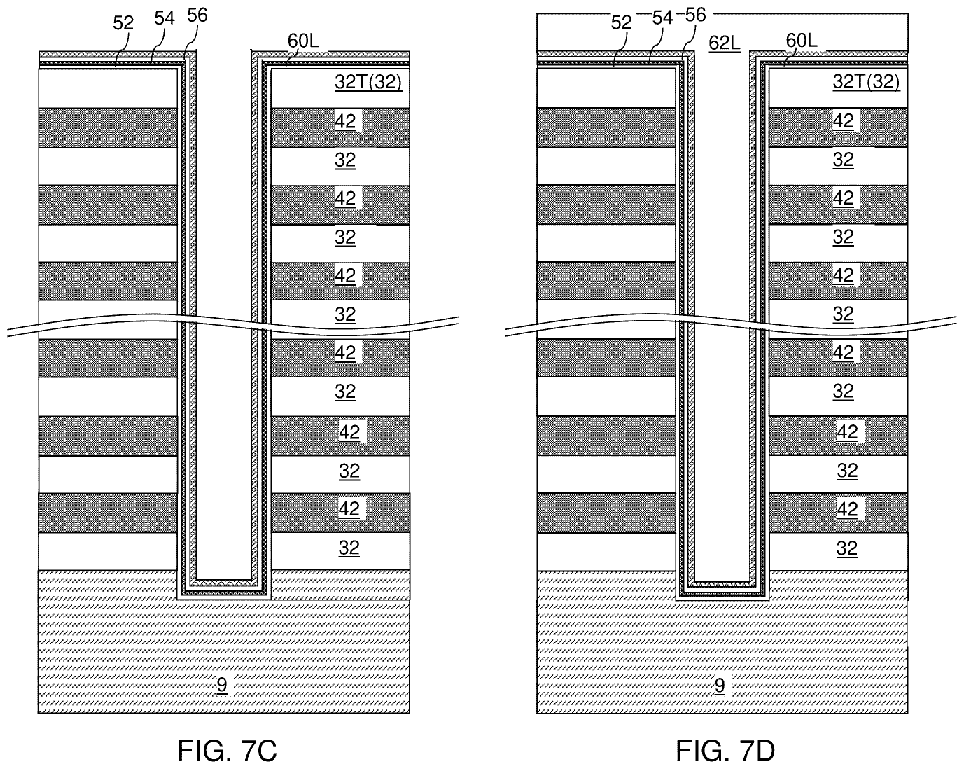

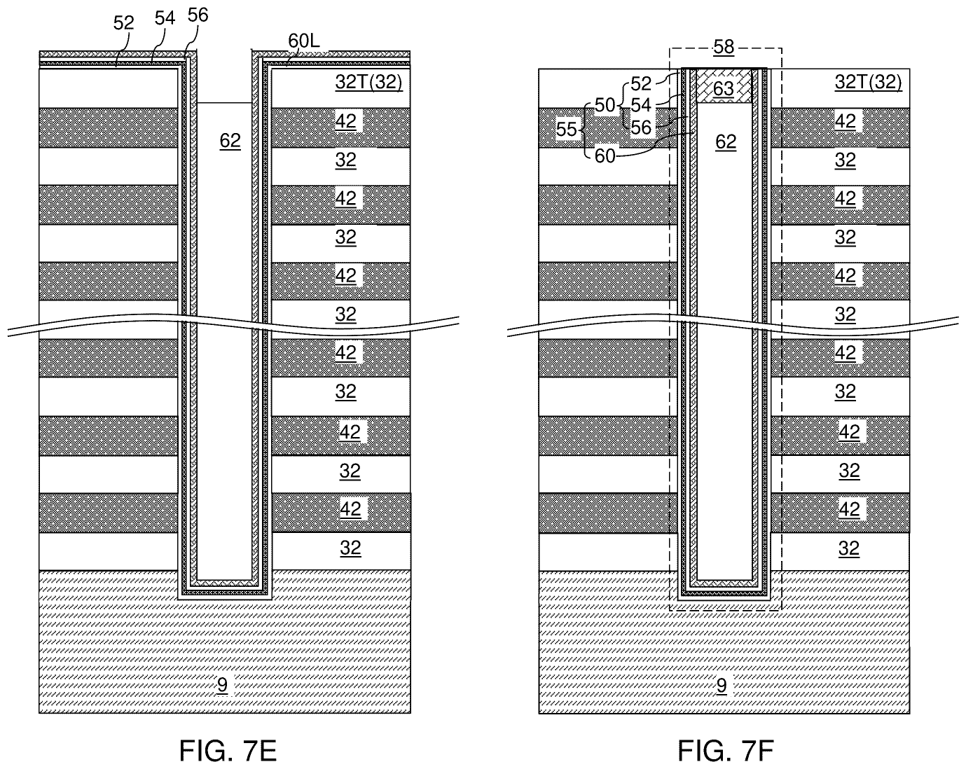

FIGS. 7A-7F are sequential vertical cross-sectional views of a memory opening 49 during formation of a memory opening fill structure 58 according to an embodiments of the present disclosure.

Referring to FIG. 7A, a memory opening 49 is illustrated after the processing steps of FIG. 6.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

Referring to FIG. 7C, a semiconductor channel material layer 60L can be deposited over each memory film 50 by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 7D, a dielectric core layer 62L comprising a dielectric fill material, such as silicon oxide, can be deposited in remaining volumes of the memory openings 49. While the dielectric core layer 62L can be deposited employing a conformal deposition process, such as a chemical vapor deposition process, the conformity of the conformal deposition process may not be perfect. Thus, the thickness of a bottom portion of the dielectric core layer 62L at the bottom of each memory opening 49 may be less than the thickness of an upper portion of the dielectric core layer 62L at the top of each memory opening 49.

Referring to FIG. 7E, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62.

Referring to FIG. 7F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings 19 at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extends predominantly along a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the drains extend along the specific direction.

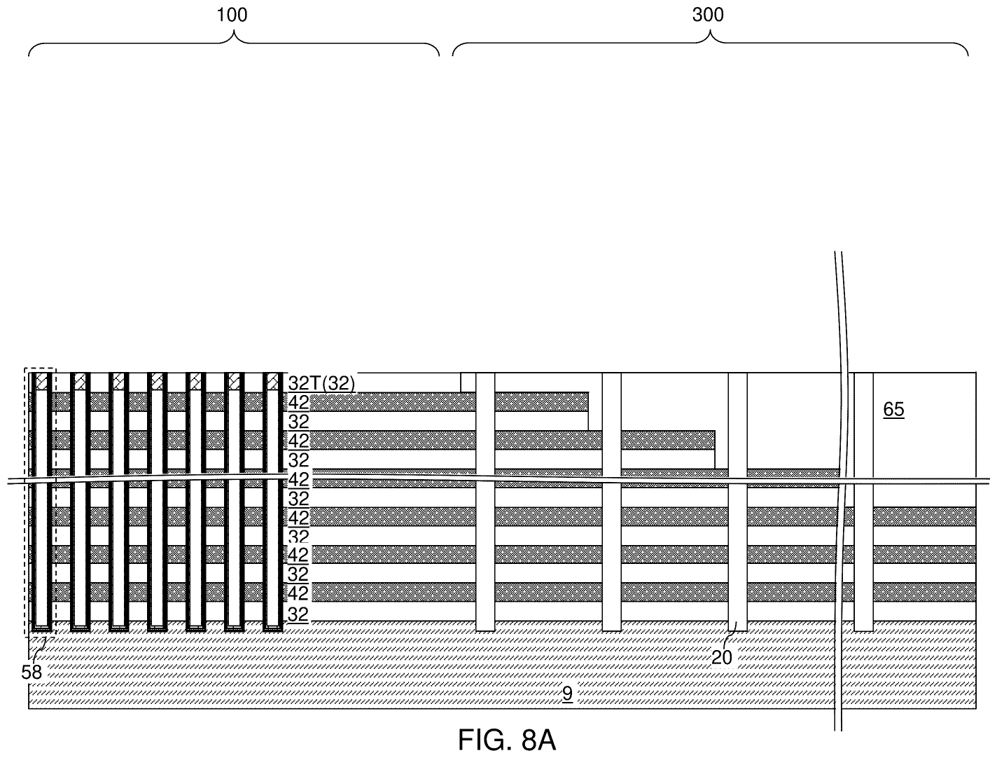

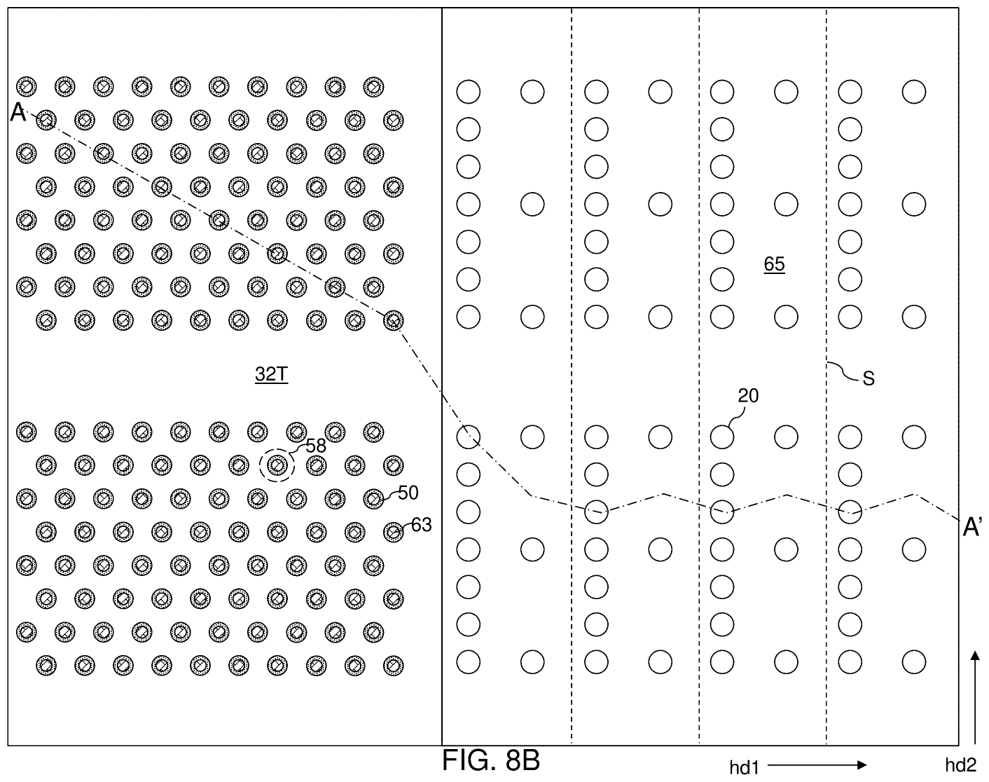

Referring to FIGS. 8A and 8B, the first exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

Thus, an alternating stack (32, 42) of insulating layers 32 and sacrificial material layers 42 is formed a substrate (such as a carrier substrate 9). The spacer material layers are formed as or are subsequently replaced with electrically conductive layers. Memory openings 49 are formed through the alternating stack (32, 42). Memory opening fill structures 58 are formed in the memory openings 49. Each of the memory opening fill structures 58 comprises a respective memory film 50 and a respective vertical semiconductor channel 60 that is laterally surrounded by the respective memory film 50. The memory opening fill structures 58 are arranged in rows laterally extending along a first horizontal direction hd1, and the rows are laterally spaced apart from each other along a second horizontal direction hd2 that is perpendicular to the first horizontal direction hd1. Each of the memory opening fill structures 58 comprises a vertical stack of memory elements (which may comprise portions of a memory film 50 located at levels of the sacrificial material layers 42), and a respective drain region 63.

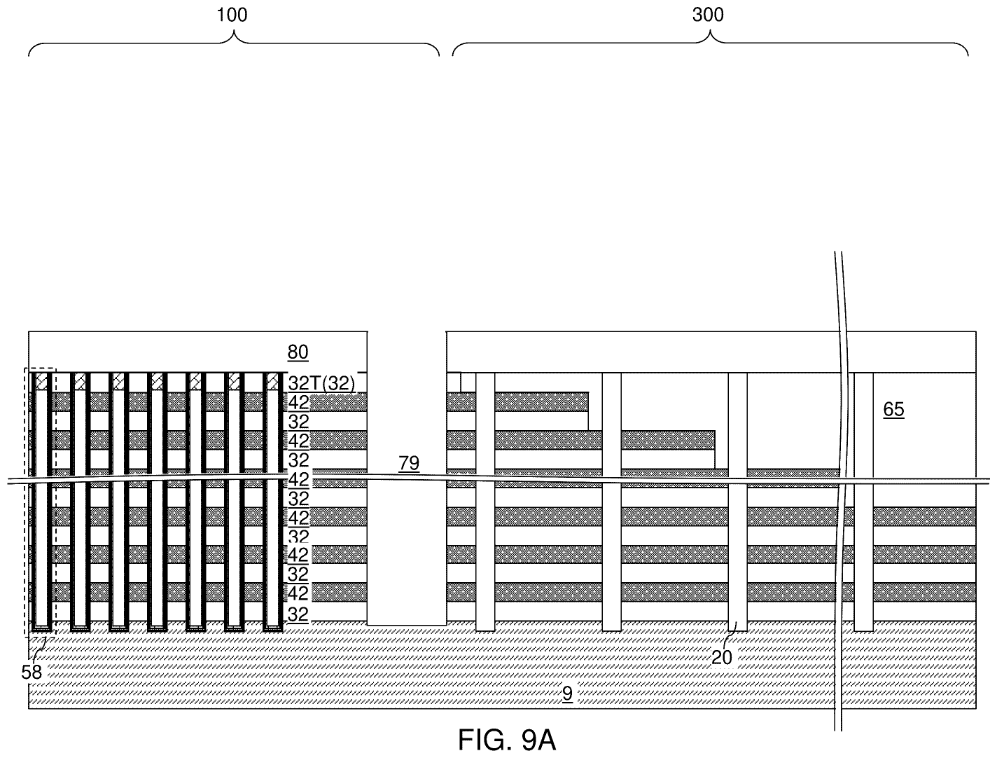

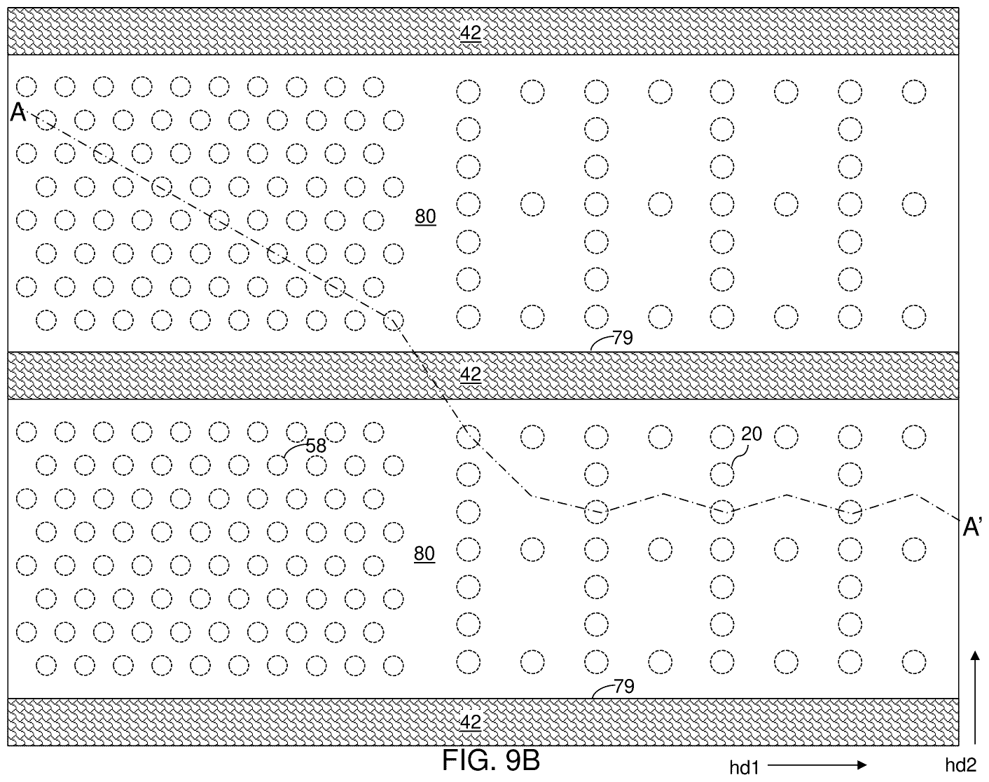

Referring to FIGS. 9A and 9B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65, and to a top surface of the carrier substrate 9. Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to the top surface of the carrier substrate 9. A surface of the carrier substrate 9 can be physically exposed underneath each lateral isolation trench 79. The photoresist layer can be subsequently removed, for example, by ashing.

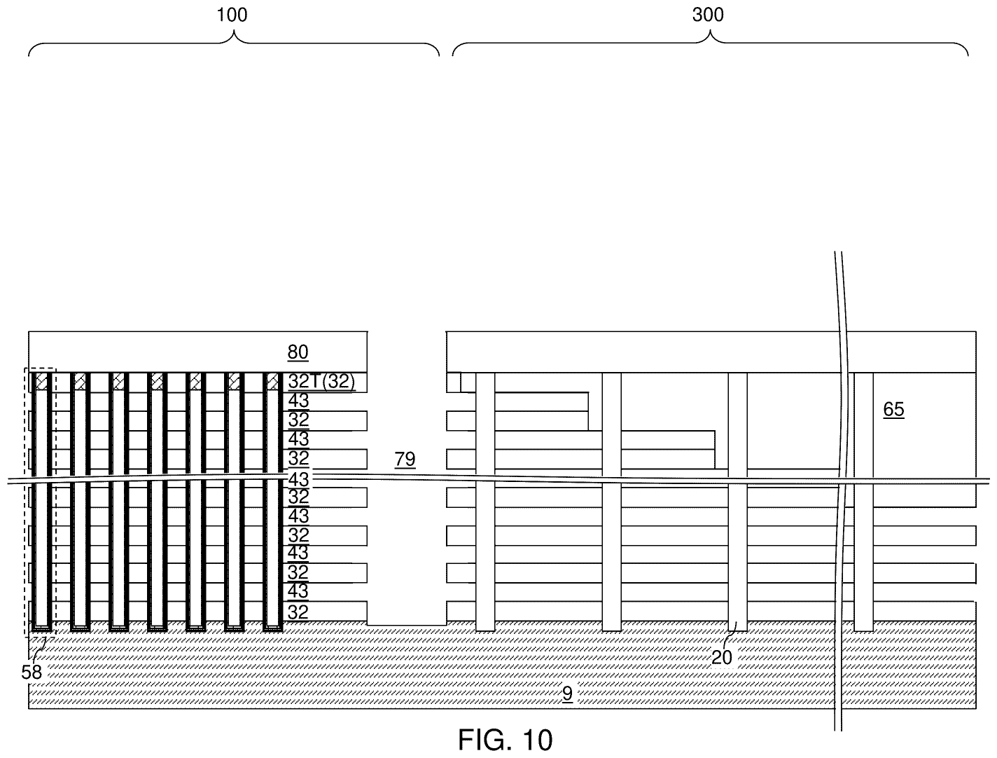

Referring to FIG. 10, an etchant that selectively etches the material of the sacrificial material layers 42 with respect to the material of the insulating layers 32 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, and various other materials employed in the art. The support pillar structure 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

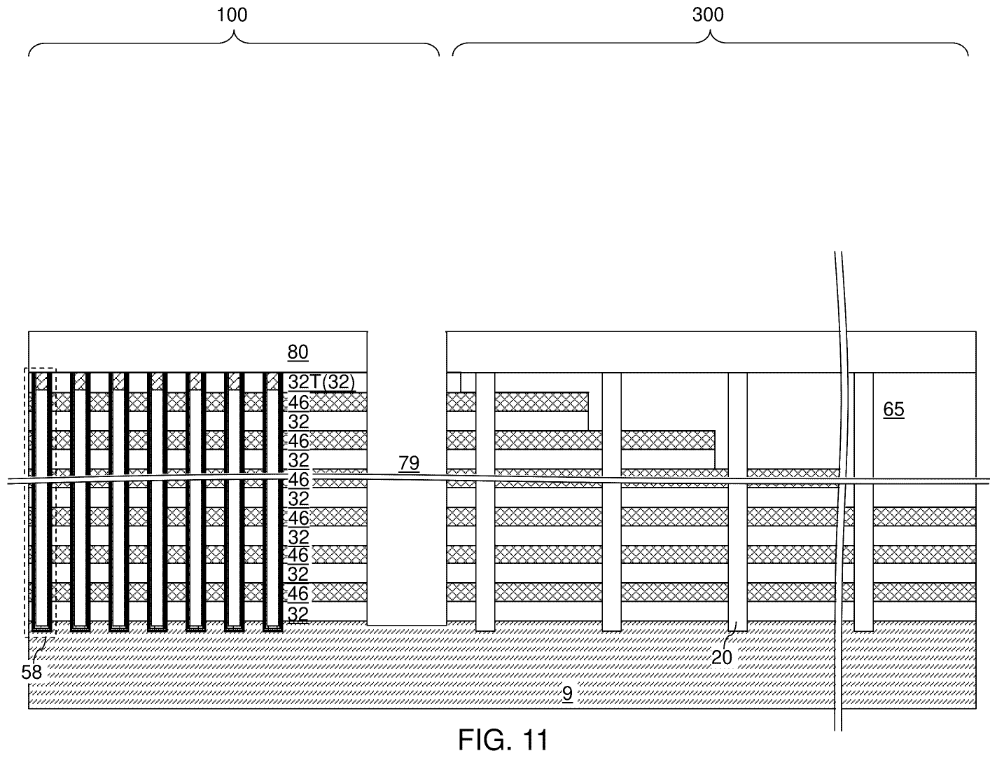

Referring to FIG. 11, an outer blocking dielectric layer (not expressly illustrated) can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the at least one the lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

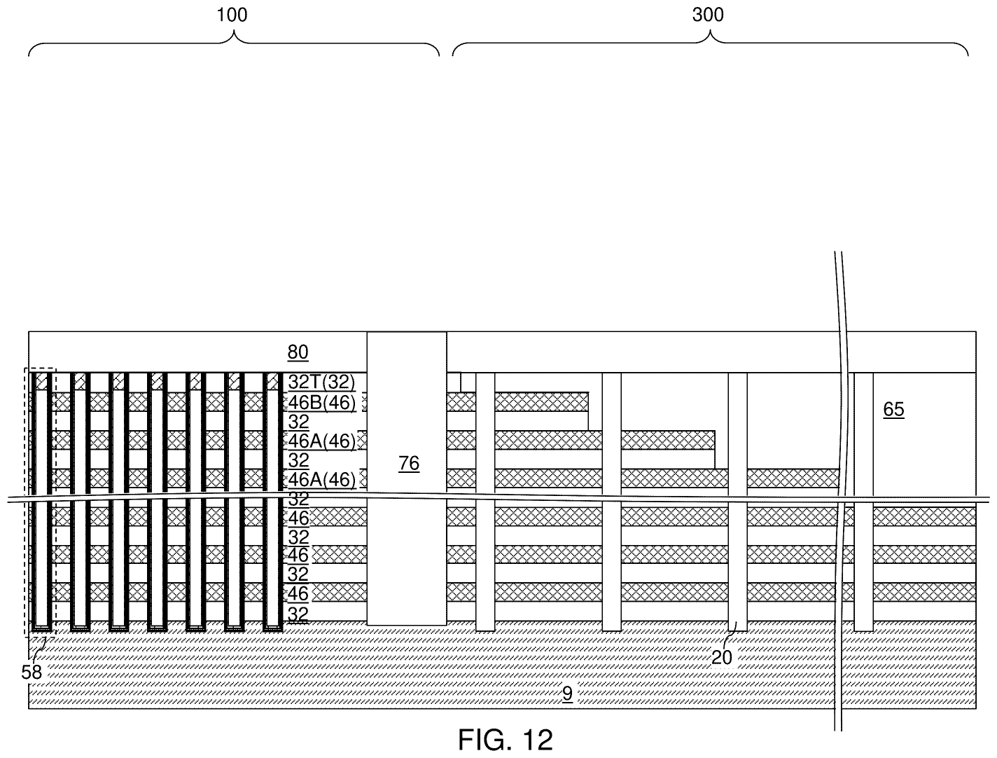

Referring to FIG. 12, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

An alternating stack (32, 46) of insulating layers 32 and electrically conductive layers 46 can be formed in a memory block area between each neighboring pair of lateral isolation trench fill structures 76. The alternating stack (32, 46) can include at least one drain-select-level electrically conductive layer (i.e., drain side select gate electrode) (46A, 46B) which is employed to activate or deactivate NAND strings (e.g., the memory opening fill structures 58 and adjacent portions of the electrically conductive layers 46) vertically extending through the alternating stack (32, 46). A subset of the electrically conductive layers 46 that underlies the drain-select-level electrically conductive layers (46A, 46B) comprises word lines, which comprise control electrodes of the NAND strings. A subset of one or more bottommost electrically conductive layers 46 which underlies the word lines comprises source side select gate electrodes. The at least one drain-select-level electrically conductive layer (46A, 46B) may comprise a single drain-select-level electrically conductive layer 46A, or may comprise a plurality of drain-select-level electrically conductive layer (46A, 46B). In one embodiment, the at least one drain-select-level electrically conductive layer (46A, 46B) may comprise at least one first electrically conductive layer 46A (e.g., one or more intermediate drain side select gate electrodes, SGD) and optional at least one second electrically conductive layer 46B (i.e., at least one top drain side select gate electrode, SGDT) that overlies the at least one first electrically conductive layer 46A. In one embodiment, the at least one first electrically conductive layer 46A may comprise a single first electrically conductive layer 46A, or a plurality of first electrically conductive layers 46A, such as 2 to 6 first electrically conductive layers 46A. In one embodiment, the at least one second electrically conductive layer 46B may comprise a single second electrically conductive layer 46B, or a plurality of second electrically conductive layers 46B, such as 2 to 3 second electrically conductive layers 46B. While an embodiment is illustrated which includes two first electrically conductive layers 46A and one second electrically conductive layer 46B, alternative embodiments are expressly contemplated herein in which different numbers of first electrically conductive layers 46A and/or different numbers of second electrically conductive layers 46B are employed.

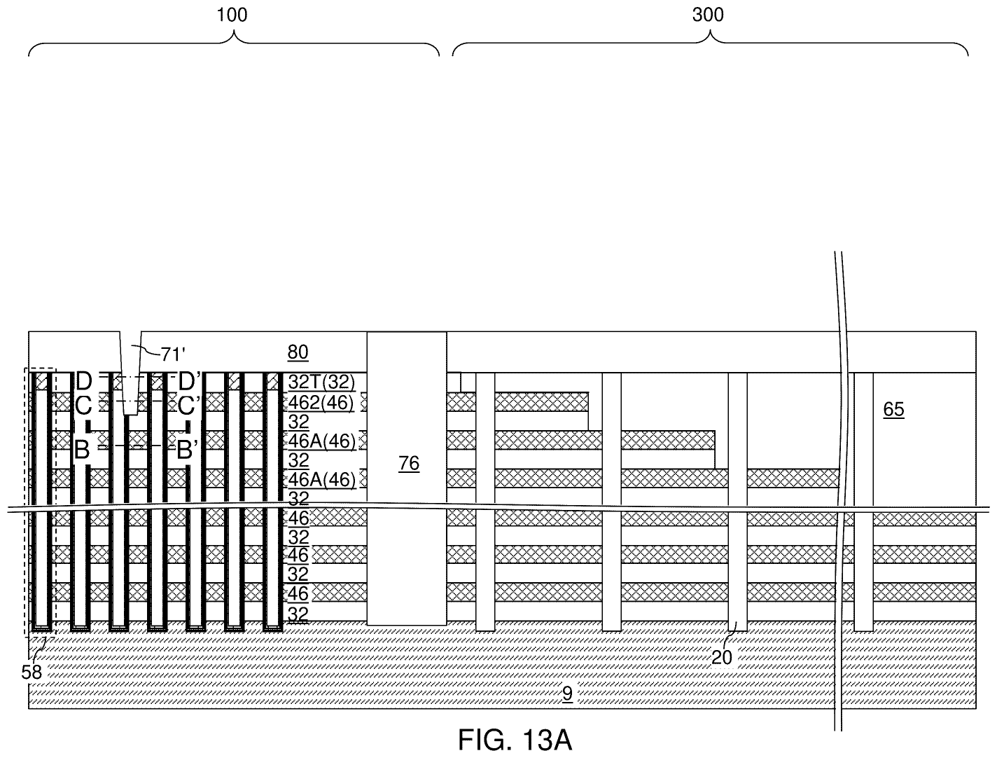

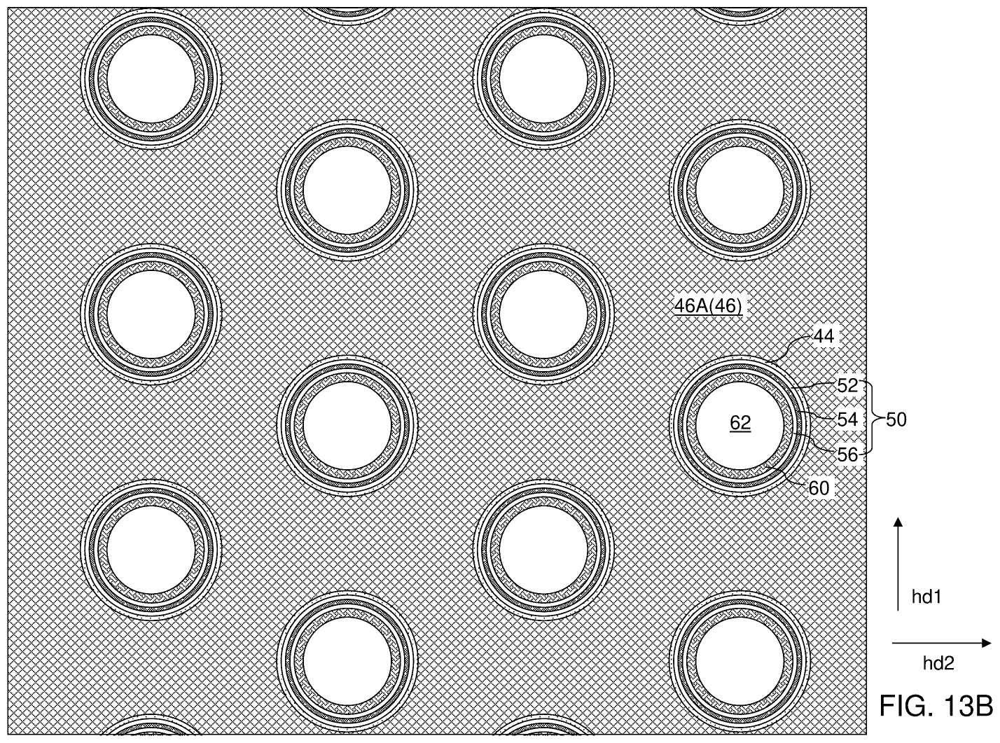

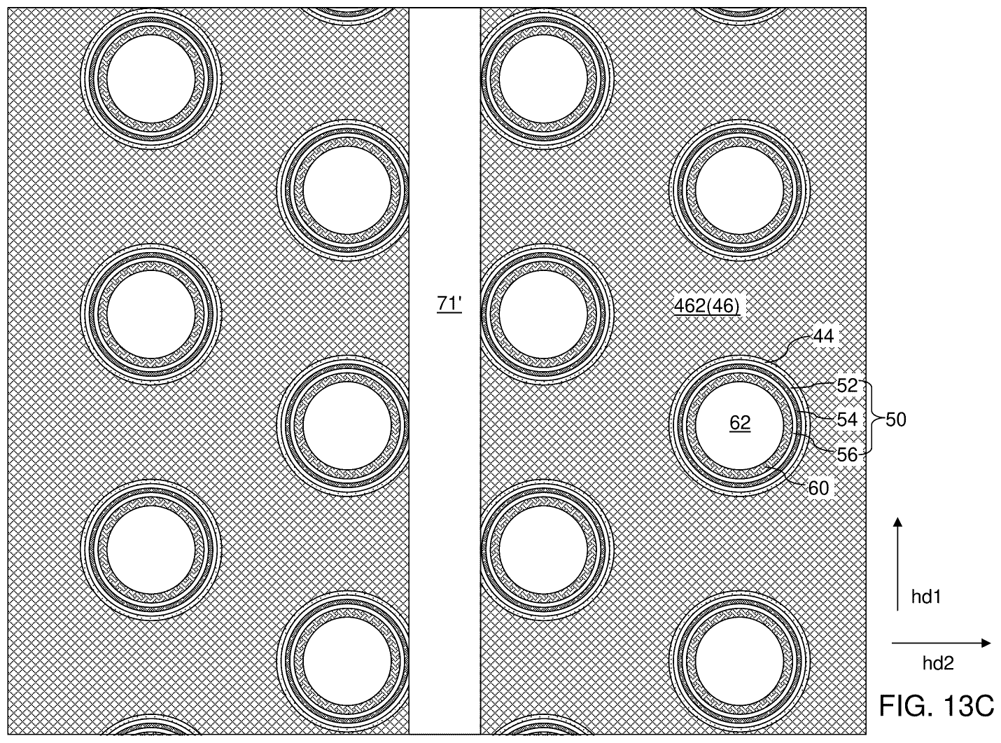

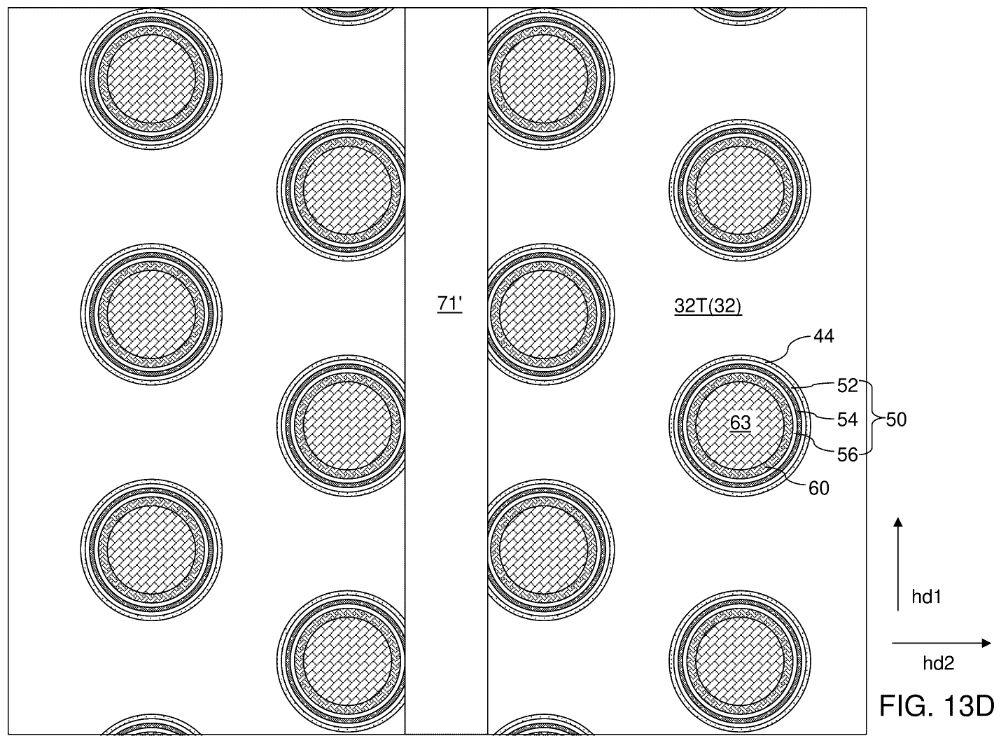

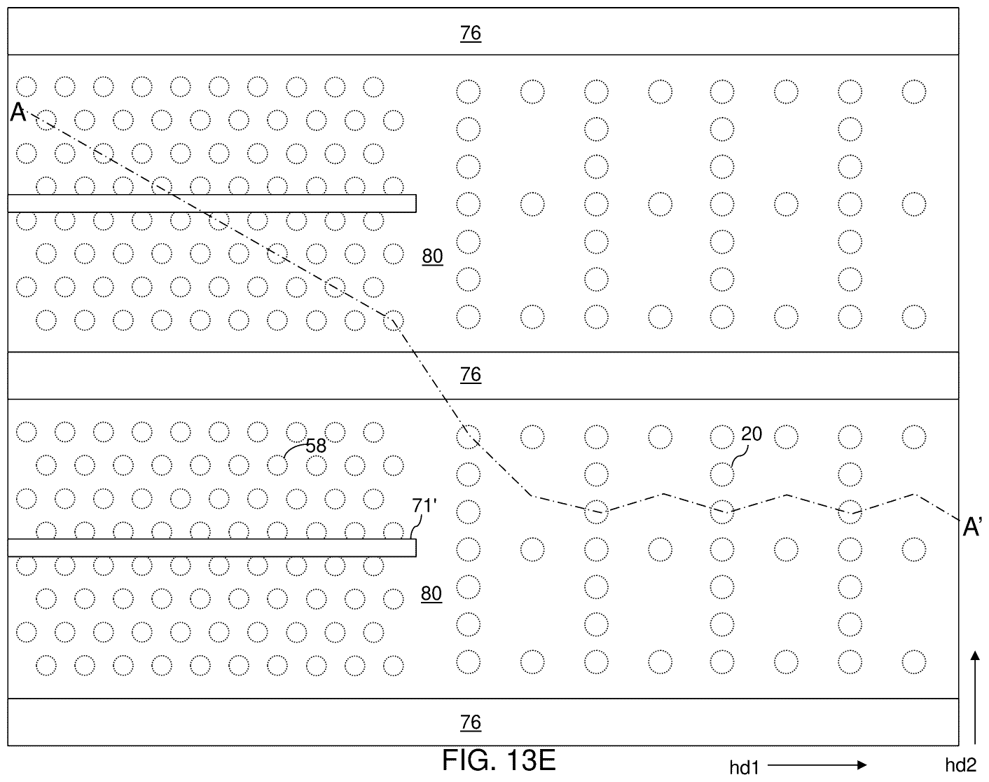

Referring to FIGS. 13A-13E, a photoresist layer (not shown) can be applied over the contact-level dielectric layer 80, and can be lithographically patterned to form line-shaped openings laterally extending along the first horizontal direction hd1 in the memory array region 100. The line-shaped openings may have horizontal cross-sectional shapes of an elongated rectangle that laterally extends between a respective neighboring pair of rows of memory opening fill structures 58, i.e., between a first row of memory opening fill structures 58 and a second row of memory opening fill structures 58. Each electrically conductive layer 46 may be embedded within a respective outer blocking dielectric layer 44, which may comprise a dielectric metal oxide material, such as aluminum oxide or titanium oxide. Each outer blocking dielectric layer 44 may have a pair of horizontally-extending portions in contact with a respective one of the insulating layers 32, and a plurality of tubular portions laterally surrounding a respective one of the memory opening fill structures 58 and connecting the pair of horizontally-extending portions. The thickness of each outer blocking dielectric layer 44 may be in a range from 1 nm to 6 nm, although lesser and greater thicknesses may also be employed.

A first anisotropic etch process can be performed to transfer the pattern of the openings in the photoresist layer through the contact-level dielectric layer 80, through the topmost insulating layer 32T, and through the at least one second electrically conductive layer 46B, if present. Trenches having horizontal cross-sectional shapes of elongated rectangles can be formed through the contact-level dielectric layer 80, through the topmost insulating layer 32T, and through the at least one second electrically conductive layer 46B, if present. These trenches cut through the at least one second electrically conductive layer 46B (if present), and are subsequently modified in a later processing step (to be subsequently described) to cut through the at least one first electrically conductive layer 46A to provide electrical isolation between electrode strips that are formed at drain select levels. These trenches are herein referred to as in-process drain-select-level isolation trenches 71′. Each patterned portion of the at least one second electrically conductive layer 46B is herein referred to as a second drain-select-level electrode strip 462. Thus, each second electrically conductive layer 46B is divided into a respective plurality of second drain-select-level electrode strips 462 that are laterally spaced apart from each other along the second horizontal direction (e.g., bit line direction) hd2 by at least one in-process drain-select-level isolation trench 71′.

In summary, the alternating stack (32, 46) comprises a second electrically conductive layer 46B that overlies a first electrically conductive layer 46A, and an in-process drain-select-level isolation trench 71′ can be formed through the second electrically conductive layer 46B by performing the first anisotropic etch process. In one embodiment, sidewalls of the in-process drain-select-level isolation trench 71′ may be straight, and may optionally cut through portions of the memory opening fill structures 58 located within the first row and the second row. In other words, the in-process drain-select-level isolation trench 71′ may be formed between a first row of memory opening fill structures 58 and a second row of memory opening fill structures 58.

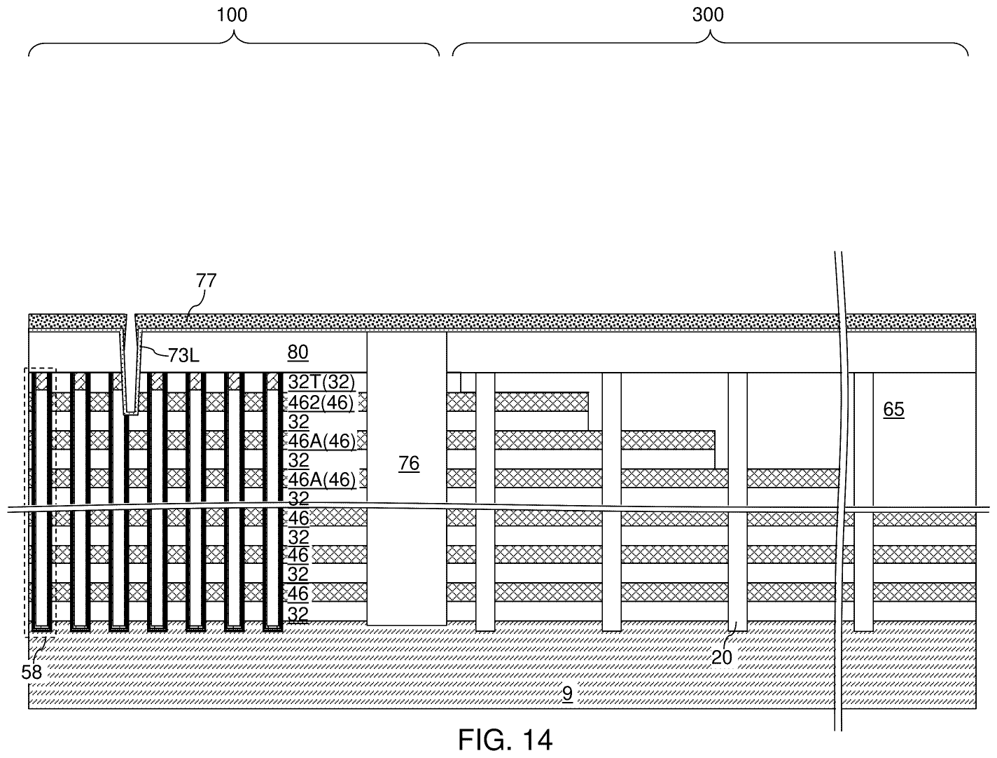

Referring to FIG. 14, a dielectric liner layer 73L can be conformally deposited over the contact-level dielectric layer 80 and in peripheral regions of the in-process drain-select-level isolation trenches 71′. The dielectric liner layer 73L comprises a dielectric material that is different from the dielectric material of the insulating layers 32. The dielectric liner layer 73L may comprise silicon nitride, silicon carbonitride, or a dielectric metal oxide, and may be deposited by a conformal deposition process such as a chemical vapor deposition process or an atomic layer deposition process. The thickness of the dielectric liner layer 73L may be in a range from 1 nm to 15 nm, such as from 2 nm to 8 nm, although lesser and greater thicknesses may also be employed. The dielectric liner layer 73L is formed in a peripheral portion of each in-process drain-select-level isolation trench 71′. The dielectric liner layer 73L can contact each of the second drain-select-level electrode strips 462, and can be located above the at least one first electrically conductive layer 46A.

An optional etch mask material layer 77 may be deposited over the dielectric liner layer 73L. Alternatively, the etch mask layer 77 may be omitted. If present, the etch mask material layer 77 comprises a material that can be employed as an etch mask material during a subsequent second anisotropic etch process that is employed to vertically extend the in-process drain-select-level isolation trench 71′. In an illustrative example, the etch mask material layer 77 may comprise a carbon-based material such as amorphous carbon, diamond-like carbon, or a commercially available patterning film such as Advanced Patterning Film™ available from Applied Materials, Inc®. In one embodiment, the etch mask material layer 77 may be deposited by a non-conformal deposition process, such as a plasma-enhanced chemical vapor deposition process. Due to the anisotropic nature of the deposition process used to deposit the etch mask material layer 77, the etch mask material layer 77 covers the top surface of the horizontally-extending portion of the dielectric liner layer 73L, and includes elongated gaps over the areas of the in-process drain-select-level isolation trenches 71′. The thickness of the horizontally-extending portion of the etch mask material layer 77 may be in a range from 20 nm to 200 nm, although lesser and greater thicknesses may also be employed.

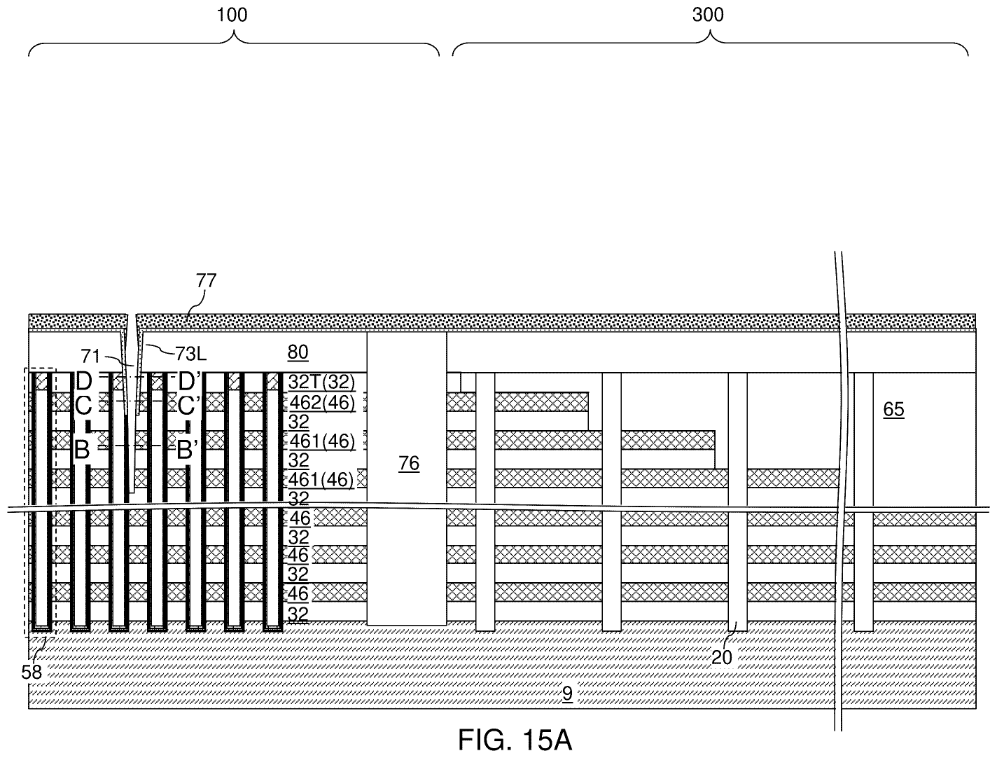

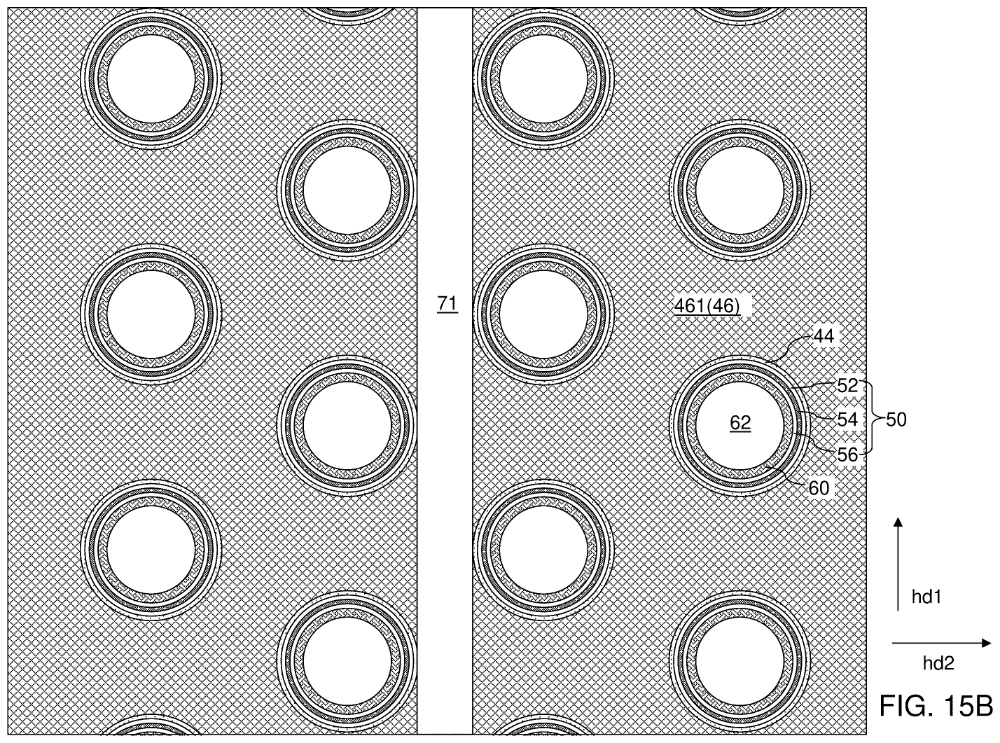

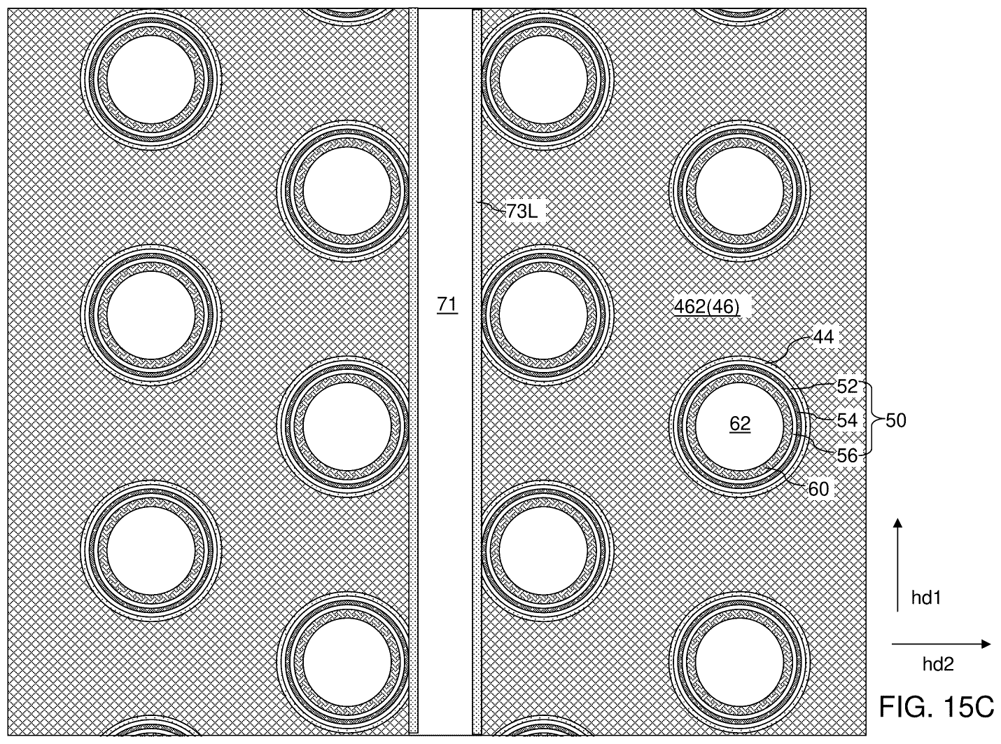

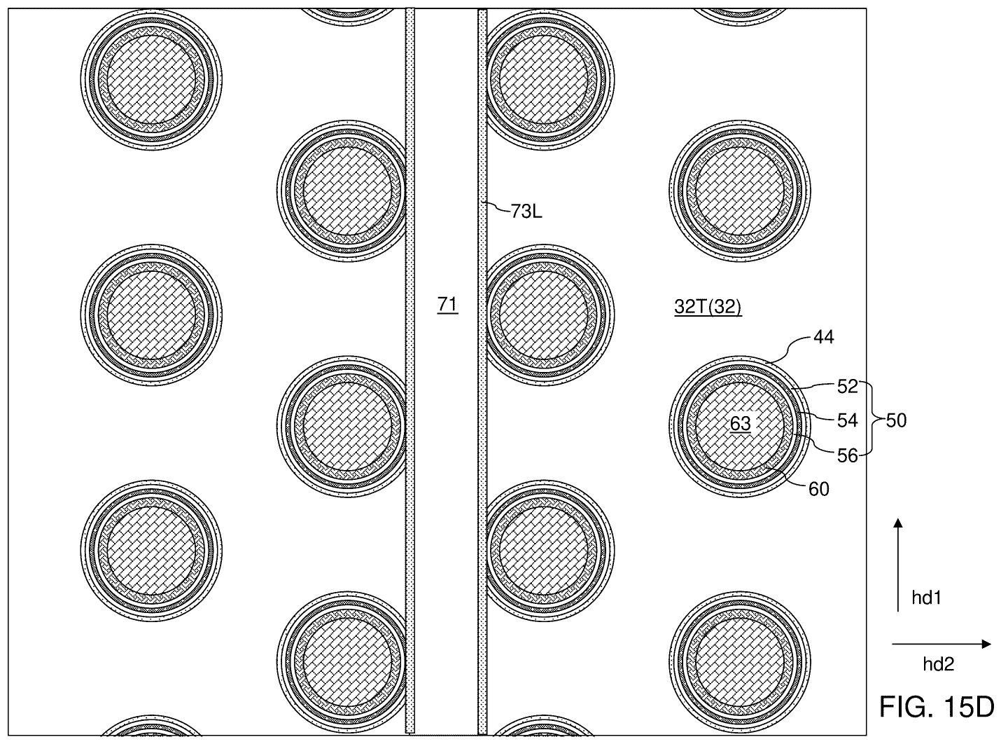

Referring to FIGS. 15A-15D, a second anisotropic etch process can be performed to etch horizontal portions of the dielectric liner layer 73L. If the etch mask material layer 77 is omitted, then the second anisotropic etch process comprises a sidewall spacer etch, such as a reactive ion etch which leaves vertical sidewall spacer portions of the dielectric liner layer 73L on sidewalls of the in-process drain-select-level isolation trenches 71′ at vertical levels of the least one second electrically conductive layer 46B. If the etch mask material layer 77 is present, then second anisotropic etch process etches the bottom portions of the dielectric liner layer 73L that is not masked by the etch mask material layer 77 from the bottom of the in-process drain-select-level isolation trenches 71′.

The second anisotropic etch process subsequently etches portions of the underlying material layers including each of the at least one first electrically conductive layer 46A without etching a subset of the electrically conductive layers 46 that is employed as word lines (which underlie the at least one first electrically conductive layer 46A). The second anisotropic etch process can etch the material of the first electrically conductive layers 46A and the material of the insulating layers 32 with a line cavity pattern having a pair of straight sidewalls that laterally extend along the first horizontal direction hd1 underneath each in-process drain-select-level isolation trench 71′. The line cavity pattern may have a horizontal cross-sectional shape of an elongated rectangle. Thus, the second anisotropic etch process vertically extends the in-process drain-select-level isolation trenches 71′ through the first electrically conductive layers 46A, and converts the in-process drain-select-level isolation trenches 71′ into drain-select-level isolation trenches 71. Each first electrically conductive layer 46A can be divided into a respective set of first drain-select-level electrode strips 461. An upper portion of each drain-select-level isolation trench 71 may be filled with a respective portion (e.g., sidewall spacer portion) of the dielectric liner layer 73L. In one embodiment, the surfaces of the first drain-select-level electrode strips 461 that are exposed to the drain-select-level isolation trenches 71 may comprise planar surface segments that are parallel the first horizontal direction hd1.

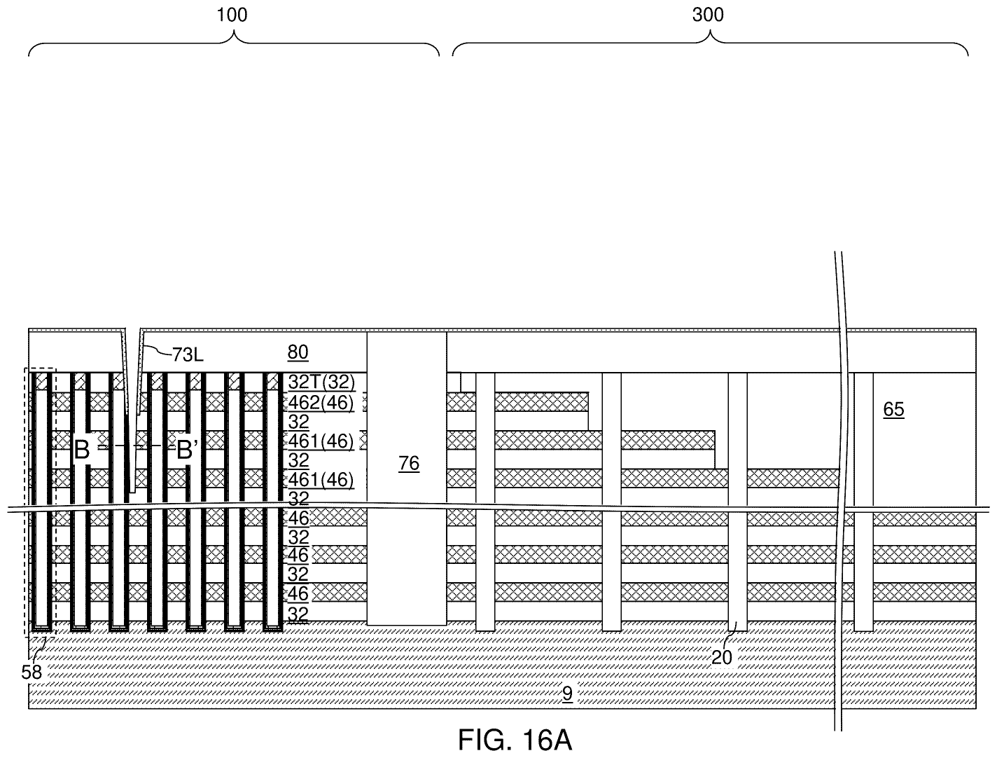

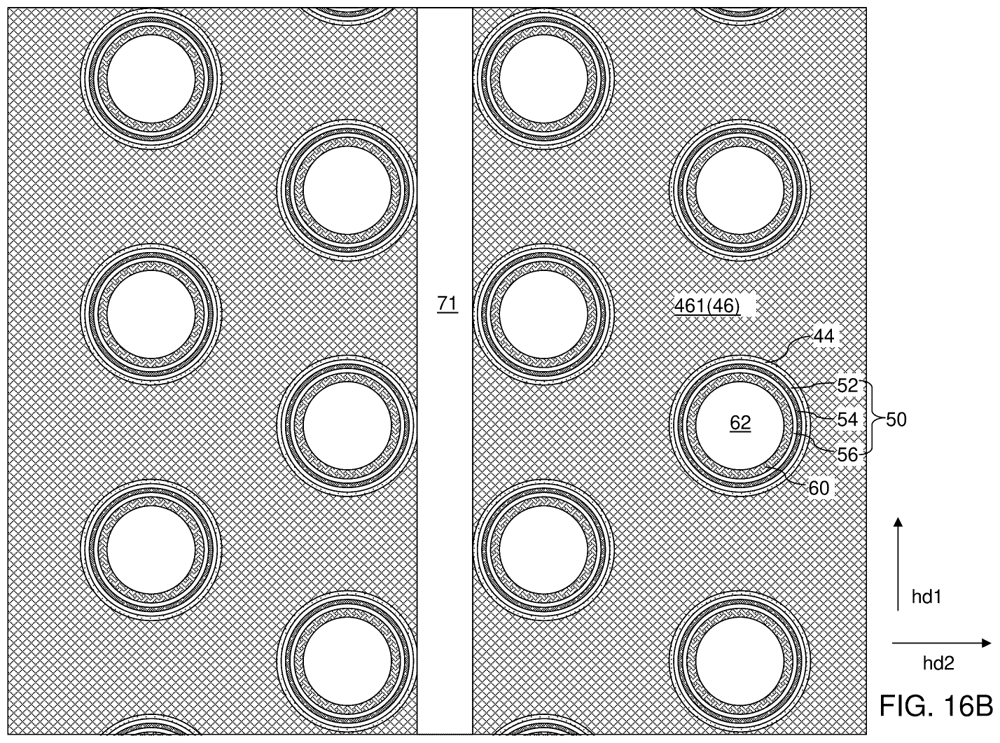

Referring to FIGS. 16A and 16B, the etch mask material layer 77 (if present) can be removed selective to the dielectric liner layer 73L, the insulating layers 32, and the electrically conductive layers 46. For example, the etch mask material layer 77 can be removed by ashing. Alternatively if the etch mask material layer 77 is omitted, then the removal step is omitted.

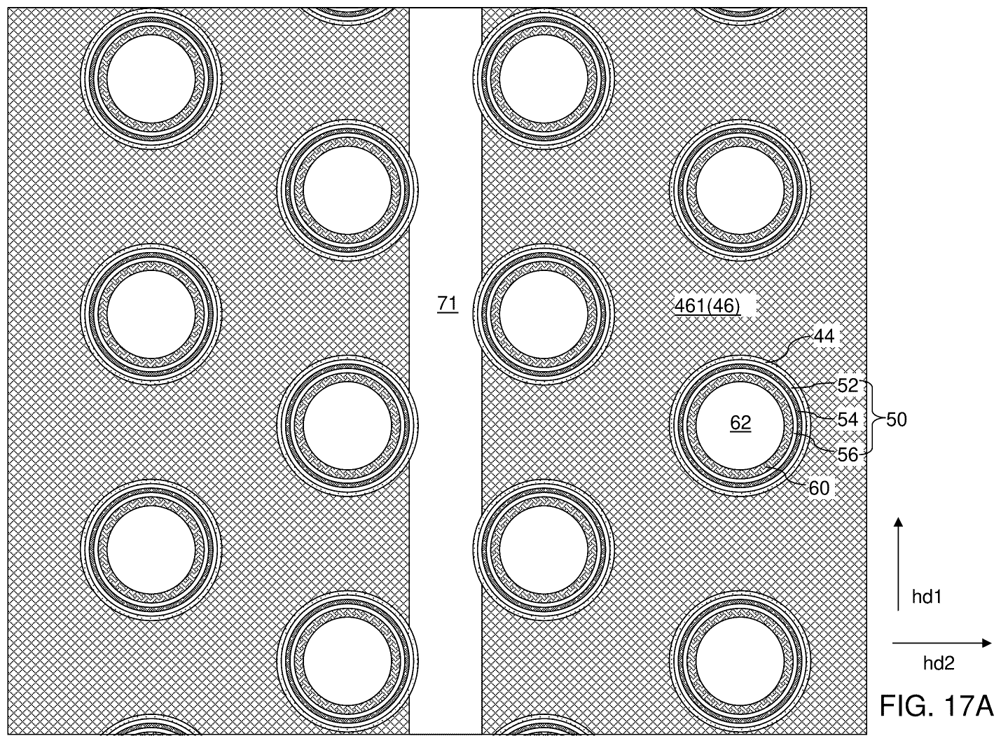

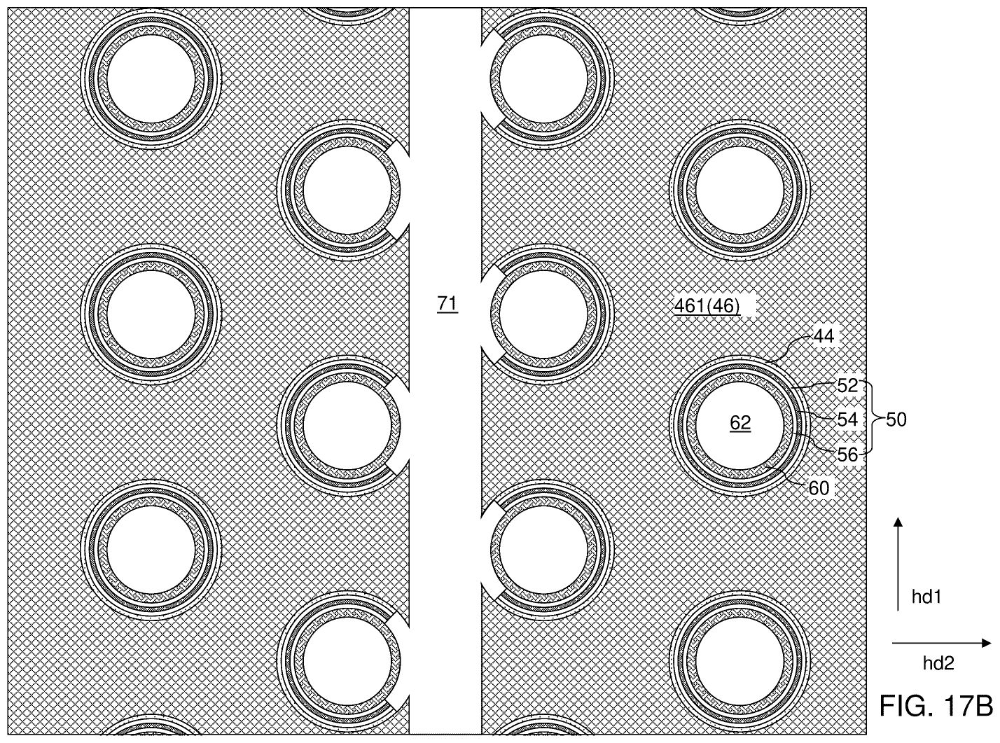

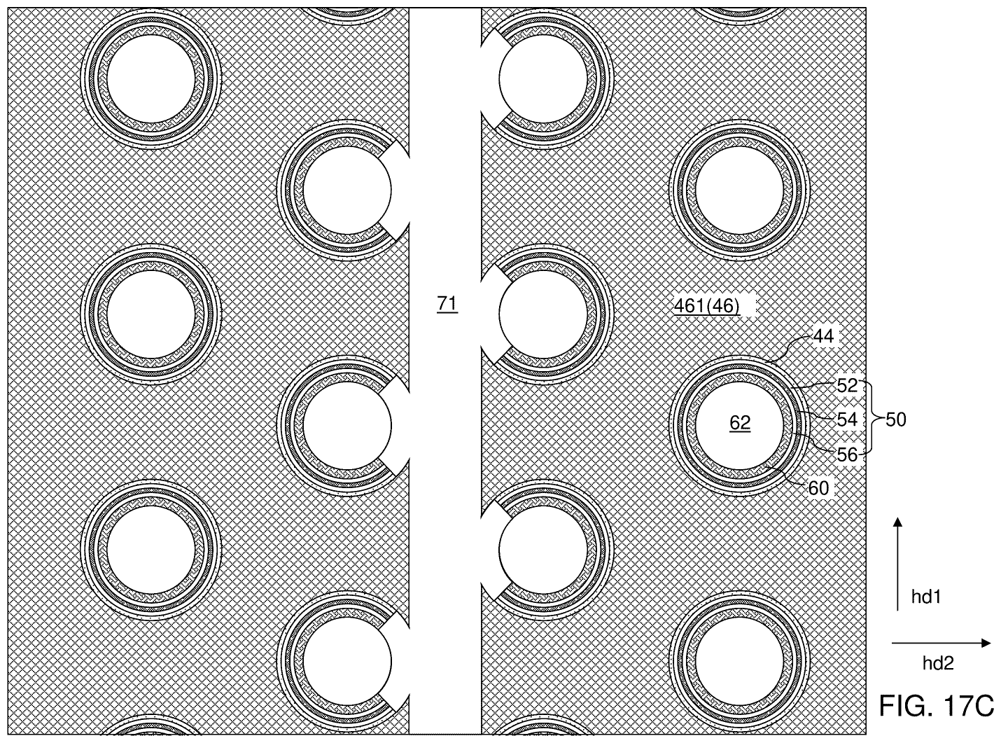

FIGS. 17A, 17B, and 17C are sequential horizontal cross-sectional views of a region of the first exemplary structure during various steps of an isotropic etch process that is employed to laterally expand the lower portion of each drain-select-level isolation trench 71.

Referring to FIGS. 17A, a first etch step of the isotropic etch process can be performed, which can have an etch chemistry that etches the material of the electrically conductive layers selective to the material of the dielectric liner layer 73L. For example, if the electrically conductive layers 46 comprise a combination of a titanium nitride barrier liner and a tungsten fill material, a wet etch process employing a mixture of hydrogen peroxide (H₂O₂) and ammonium hydroxide (NH₄OH) or a mixture of hydrogen peroxide and sulfuric acid may be employed for the first etch step of the isotropic etch process. The first etch step may collaterally etch the insulating layers 32 and proximal portions of the memory films 50 at etch rates that are lower than the etch rate for the materials of the electrically conductive layers 46.

For example, a drain-select-level isolation trench 71 may be formed between a first row of memory opening fill structures 58 arranged along the first horizontal direction hd1 and a second row of memory opening fill structures 58 arranged along the first horizontal direction hd1. The first row and the second row may be a pair of neighboring rows that are spaced from each other along the second horizontal direction hd2. In one embodiment, the memory opening fill structures 58 in the first row may be laterally offset from the memory opening fill structures 58 in the second row along the first horizontal direction hd1 by one half of the pitch of the memory opening fill structures 58 in each row of memory opening fill structures 58. The duration of the first etch step can be selected such that each of the memory opening fill structures 58 located within a pair of neighboring rows of memory opening fill structures 58 adjacent to each drain-select-level isolation trench 71 have surface segments that are exposed to the respective drain-select-level isolation trench 71. In one embodiment, the physically exposed surface segments of the memory opening fill structures 58 may be a laterally-convex and vertically-straight surface segments. As used herein, a laterally-convex surface segment refers to a surface segment that has a convex profile in a horizontal cross-sectional view. As used herein, a laterally-concave surface segment refers to a surface segment that has a concave profile in a horizontal cross-sectional view. As used herein, a vertically-straight surface segment refers to a surface segment that has a straight profile in a vertical cross-sectional view.

Referring to FIG. 17B, a second etch step of the isotropic etch process can be performed to etch the materials of the outer blocking dielectric layers 44 and the memory films 50 selective to the material of the vertical semiconductor channels 60. In one embodiment, each memory film 50 may comprise a layer stack of a blocking dielectric layer 52, a memory material layer 54, and a tunneling dielectric layer 56. In an illustrative embodiment, the outer blocking dielectric layer 44 comprises aluminum oxide, the blocking dielectric layer 52 comprises silicon oxide, the memory material layer 54 comprises silicon nitride as a charge trapping material, and the tunnelling dielectric layer 56 comprises an ONO stack. In this embodiment, the second step of the isotropic etch process may comprise a sequence of wet etch steps, such as a first wet etch step employing a mixture of phosphoric acid, acetic acid, and nitric acid for etching aluminum oxide, a second wet etch step employing dilute hydrofluoric acid for etching silicon oxide, a third wet etch step employing phosphoric acid for etching silicon nitride, and a fourth wet etch step that sequentially applies dilute hydrofluoric acid, phosphoric acid, and dilute hydrofluoric acid for etching the ONO stack. Portions of the outer blocking dielectric layers 44 and the memory films 50 that are proximal to a drain-select-level isolation trench 71 can be removed at the levels of the first drain-select-level electrode strip 461 while the dielectric liner layer 73L (or remaining sidewall spacers thereof) protects the second drain-select-level electrode strips 462 from etching.

Referring to FIG. 17C, a third etch step of the isotropic etch process can be performed to etch portions of the vertical semiconductor channels 60 that are exposed to the drain-select-level isolation trenches 71. For example, a wet etch process employing hot trimethyl-2 hydroxyethyl ammonium hydroxide (“hot TMY”) or tetramethyl ammonium hydroxide (TMAH) may be performed to etch portions of polysilicon or amorphous silicon vertical semiconductor channels 60 that are exposed to the drain-select-level isolation trenches 71.

The isotropic etch process including the first, second, and third etch steps described with reference to FIGS. 17A-17C laterally expands each drain-select-level isolation trench 71 at the level(s) of the first drain-select-level electrode strips 461 without expanding it at the level(s) of the second drain-select-level electrode strips 462. Thus, the wider second drain-select-level electrode strips 462 may be used in gate induced drain leakage (GIDL) current erase step without a decrease in the erase performance level.

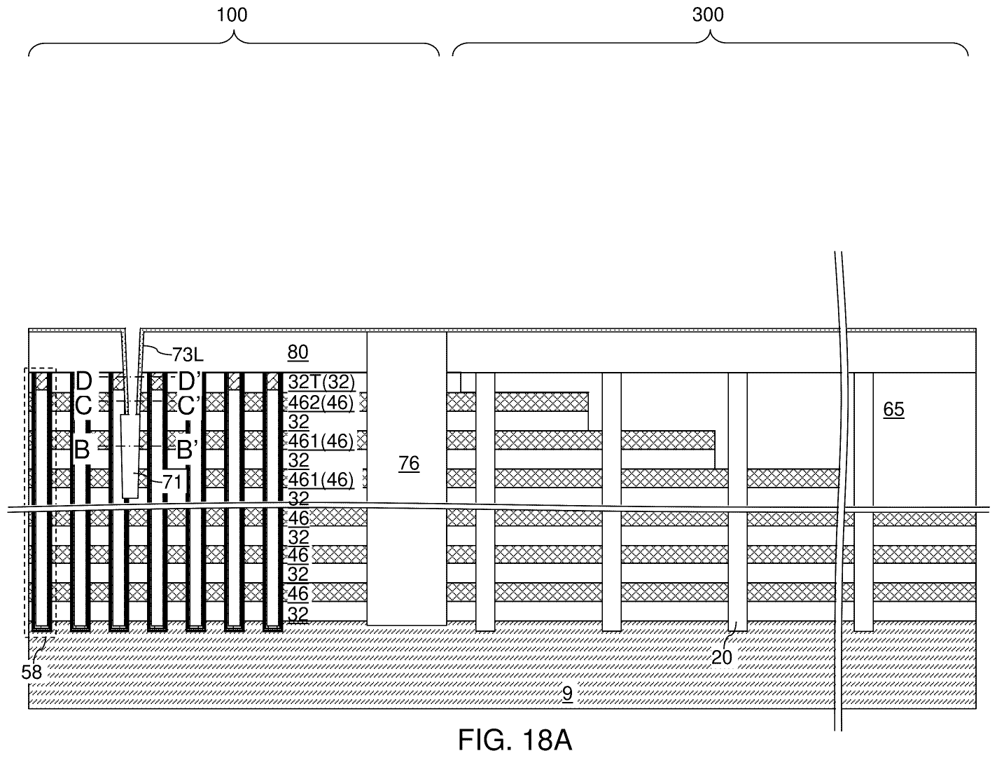

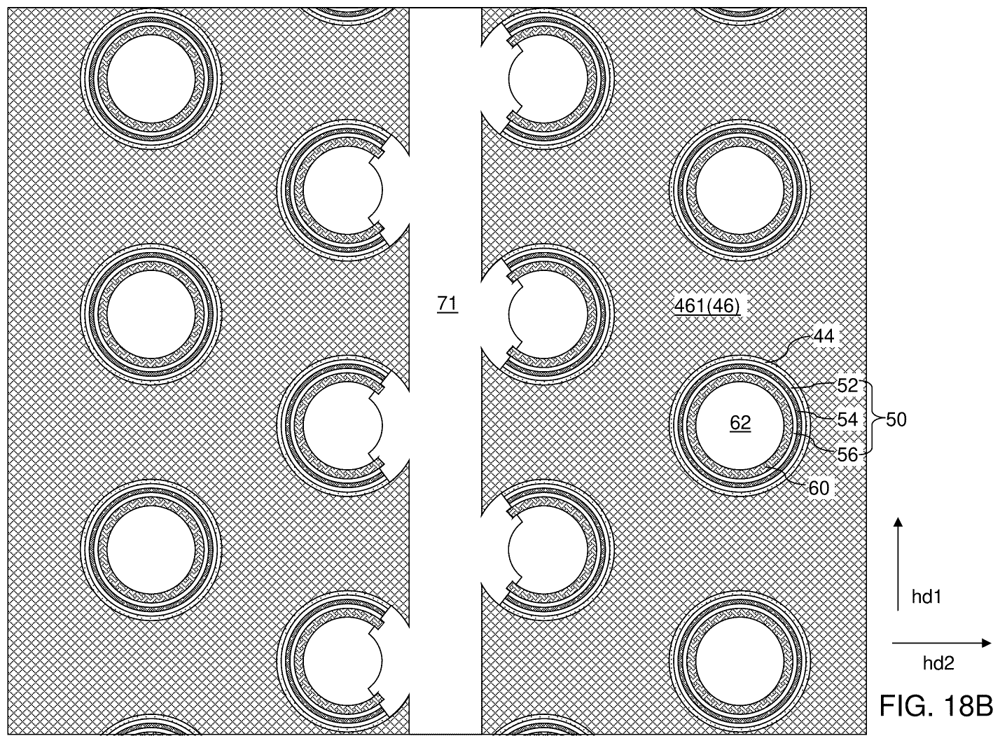

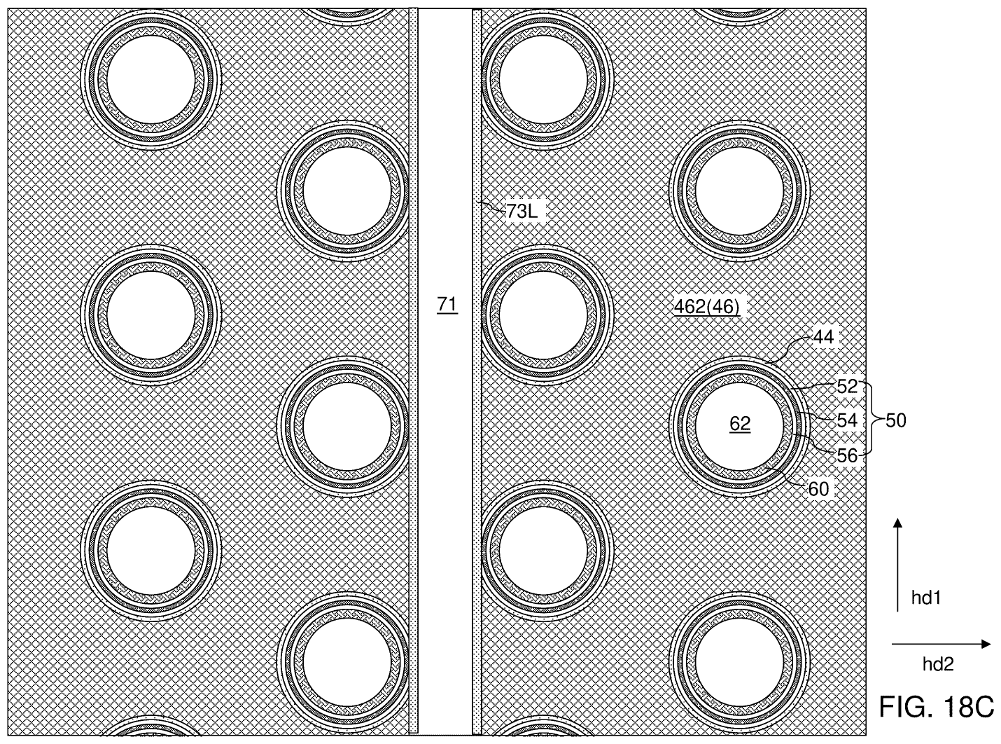

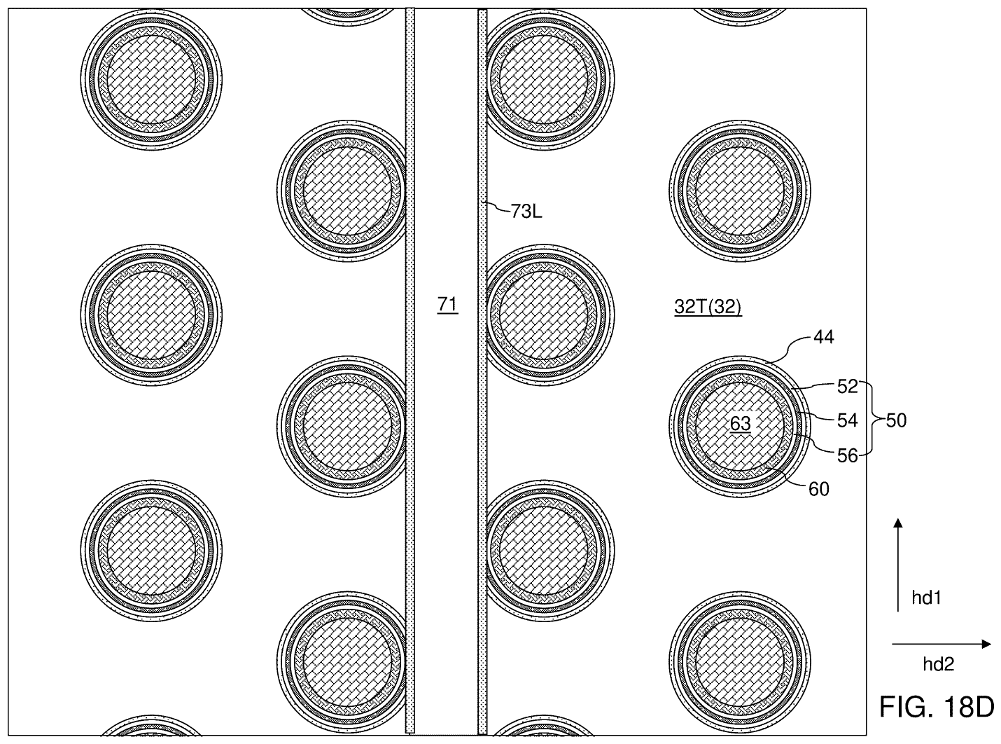

Referring to FIGS. 18A-18D, the isotropic etch process may optionally comprise a fourth etch step in which portions of the dielectric cores 62 that are exposed to the drain-select-level isolation trenches 71 are laterally recessed. In this case, a wet etch process employing dilute hydrofluoric acid may be employed for the fourth etch step to etch a silicon oxide dielectric core 62. Portions of the insulating layers 32 that are exposed to the drain-select-level isolation trenches 71 may be collaterally recessed, while the dielectric liner layer 73L (or sidewall spacers thereof) protects the second drain-select-level electrode strips 462 and a subset of the insulating layers 32 that overlie the first drain-select-level electrode strips 461.

Each drain-select-level isolation trench 71 as provided at the processing steps of FIGS. 16A and 16B includes a respective volume of a cavity having a line cavity pattern. Each drain-select-level isolation trench 71 after the processing steps described with reference to FIGS. 18A-18D includes a respective volume of a cavity that is formed by expansion of the line cavity pattern at the vertical levels of the first drain-select-level electrode strips 461, but not at the vertical levels of the overlying second drain-select-level electrode strips 462. Each drain-select-level isolation trench 71 can be formed between a respective first row of memory opening fill structures 58 and a respective second row of memory opening fill structures 58. Gaps are present between memory opening fill structures 58 within each row of memory opening fill structures 58 arranged along the first horizontal direction hd1. Each drain-select-level isolation trench 71 after the processing steps of FIG. 17C and/or the processing steps of FIGS. 18A-18D laterally protrudes into each memory opening fill structure 58 in the first row and the second row, and does not laterally protrude into the first drain-select-level electrode strips 461 within gaps between neighboring pairs of the memory opening fill structures 58 that are laterally spaced along the first horizontal direction hd1 in the first and the second rows.

In one embodiment, each of the memory opening fill structures 58 comprises a respective dielectric core 62 that is laterally surrounded by a respective vertical semiconductor channel 60, and each dielectric core 62 in the first row and the second row may be exposed to the drain-select-level isolation trench 71. In one embodiment, surface segments of each inner sidewall of the vertical semiconductor channels 60 in the memory opening fill structure 58 within the first row and the second row may be exposed to the drain-select-level isolation trench 71. In one embodiment, horizontally-convex and vertically-straight surface segments of the dielectric cores 62 within the first row and the second row can be exposed to the drain-select-level isolation trench 71. Surface segments of sidewalls of the first drain-select-level electrode strips 461 can be physically exposed to cavities that are formed within the volumes of the memory openings 49 upon lateral expansion of the drain-select-level isolation trenches 71. Portions of the first drain-select-level electrode strips 461 that are located within gaps between the neighboring pairs of memory opening fill structures 58 (which are laterally spaced along the first horizontal direction hd1) may comprise straight and planar sidewall segments that are parallel to the first horizontal direction hd1 and exposed to the drain-select-level isolation trench 71. Thus, the ungated portions of the outer blocking dielectric layer 44 are reduced or eliminated, and all portions of the outer blocking dielectric layer 44 are located adjacent to a respective first drain-select-level electrode strips 461 in the respective vertical level, which is believed to reduce electron de-trapping from memory material layer 54.

Generally, a drain-select-level isolation trench 71 can be formed through a subset of electrically conductive layers 46 including a first electrically conductive layer 46A such that the drain-select-level isolation trench 71 divides the first electrically conductive layer 46A into a pair of first drain-select-level electrode strips 461. The drain-select-level isolation trench 71 includes volumes formed by removal of portions of a first row of memory opening fill structures 58 and a second row of memory opening fill structures 58. Each lateral protrusion of the horizontal cross-sectional shape of the drain-select-level isolation trench 71 cuts through an edge portion of a respective one of the memory opening fill structures 58. Formation of damaged and/or ungated portions of the outer blocking dielectric layers 44 can be avoided or minimized, to avoid or minimize the electron de-trapping.

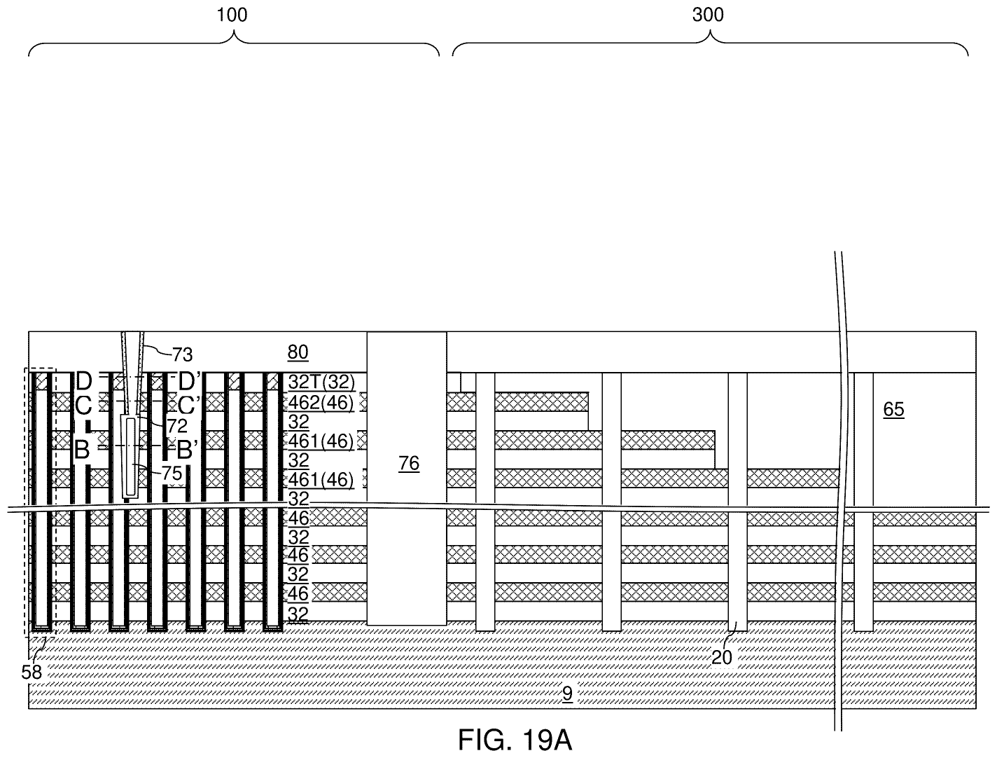

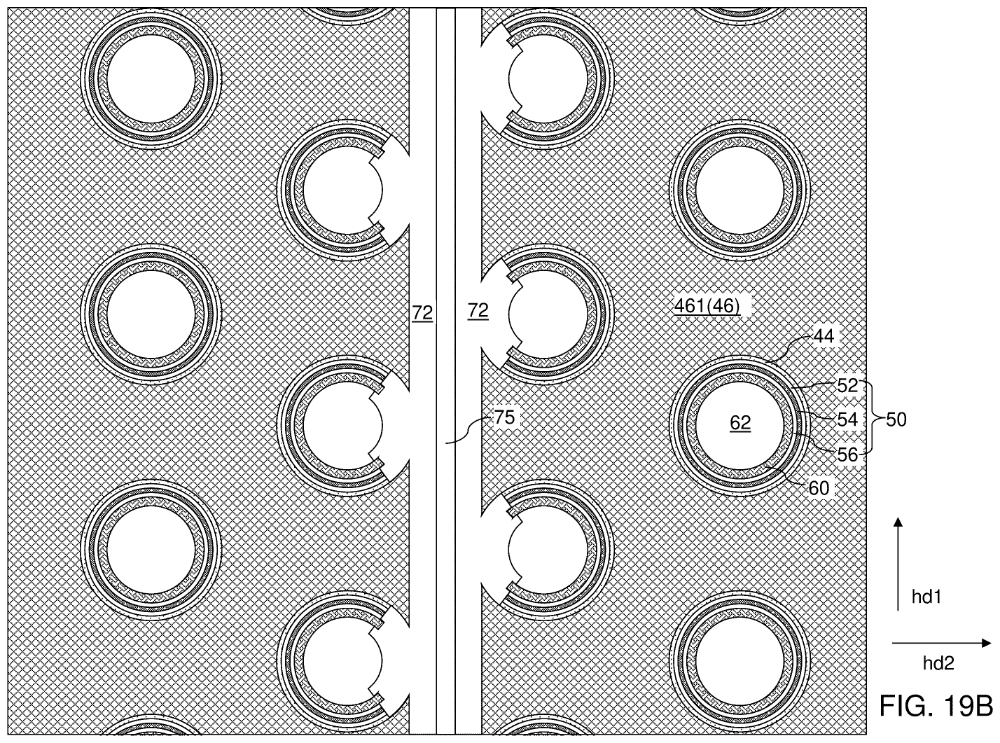

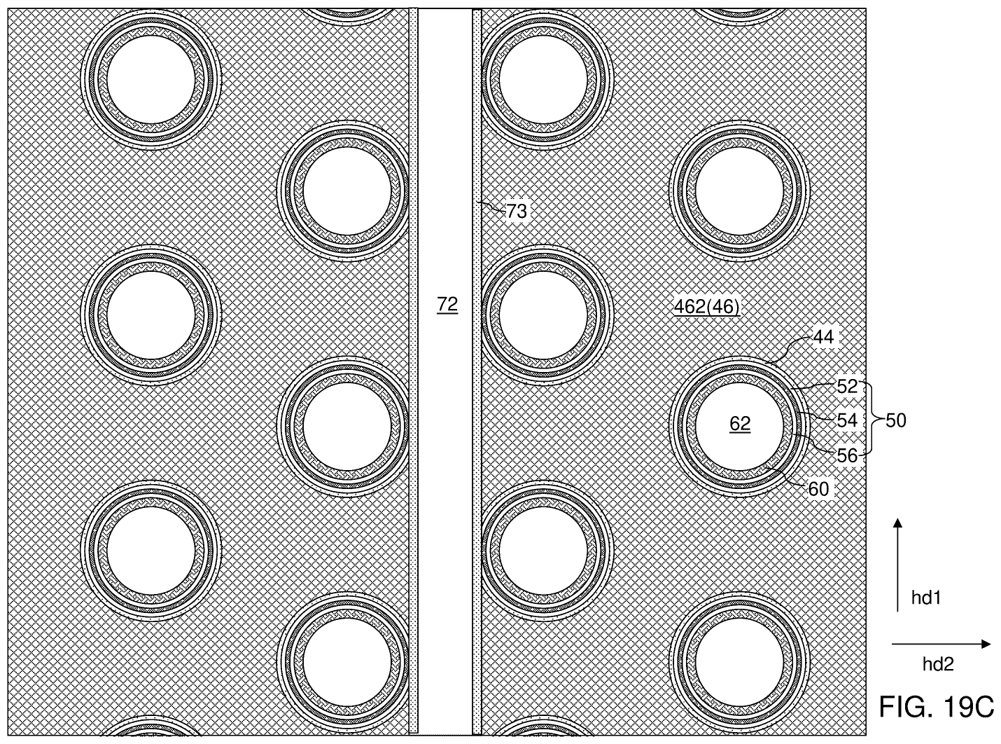

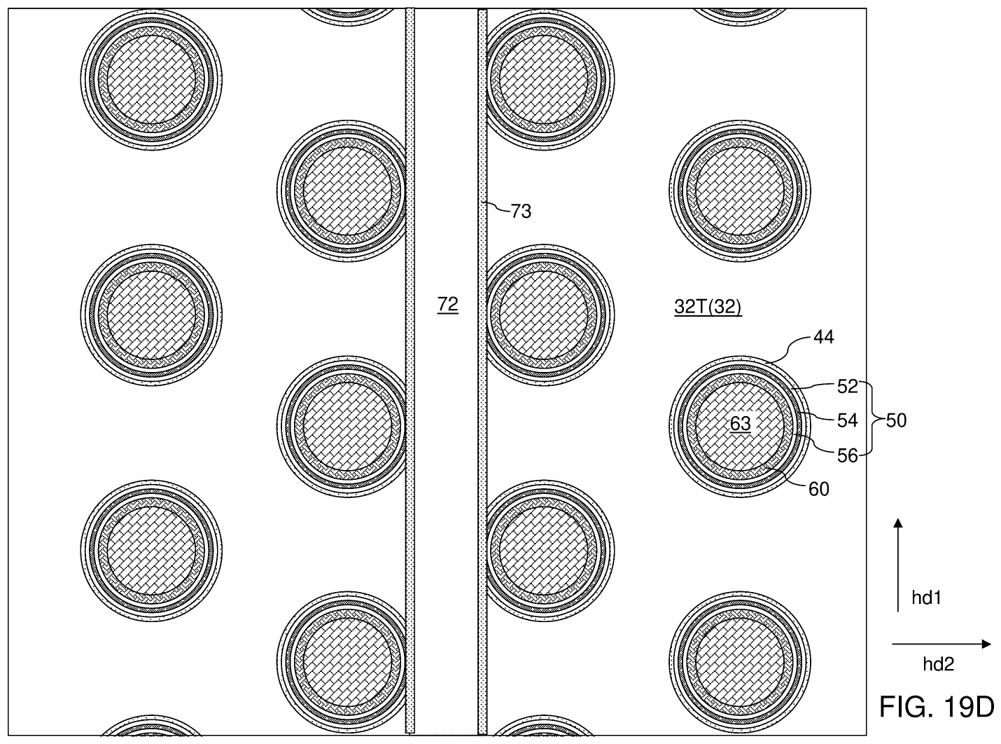

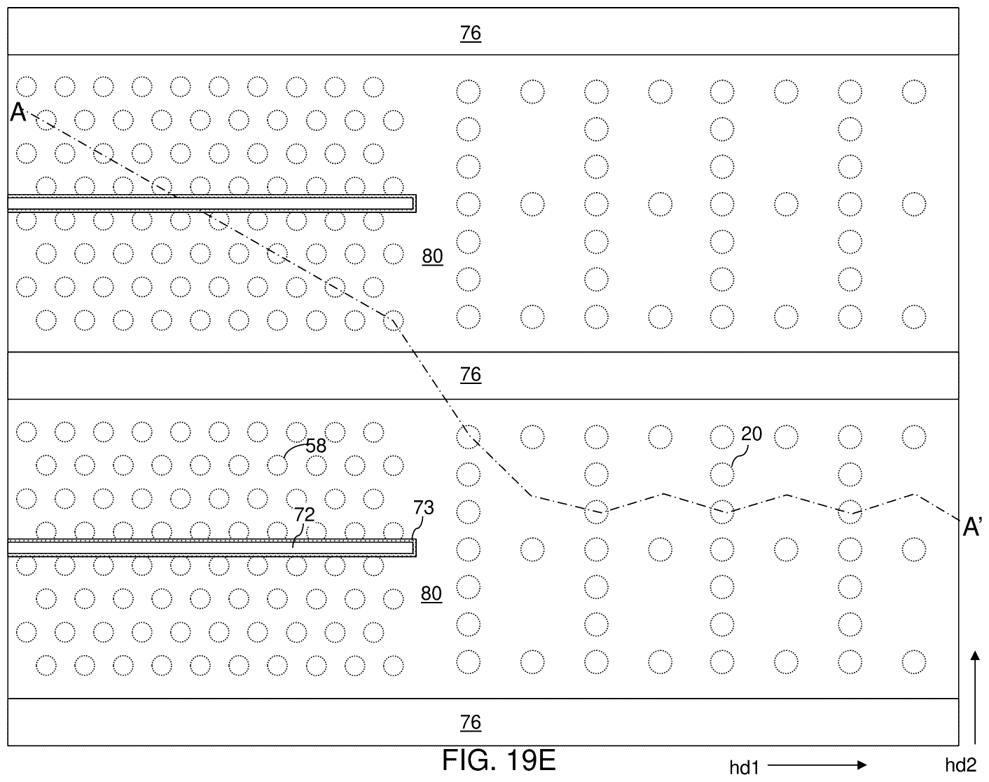

Referring to FIGS. 19A-19E, the dielectric liner layer 73L may optionally be removed selective to the contact-level dielectric layer 80 and the alternating stack (32, 46). A dielectric fill material can be conformally deposited in volumes of the voids in the drain-select-level isolation trenches 71. The dielectric fill material may comprise a planarizable dielectric material, such as undoped silicate glass (i.e., silicon oxide) or a doped silicate glass. Portions of the dielectric fill material and the dielectric liner layer 73L that overlie the horizontal plane including the top surface of the contact-level dielectric layer 80 can be removed by performing a planarization process, which may employ a chemical mechanical polishing process. Each remaining portion of the dielectric fill material that remains in a respective drain-select-level isolation trench 71 constitutes a dielectric fill material portion 72. Each remaining portion of the dielectric liner layer 73L (if any) that remains in a respective drain-select-level isolation trench 71 constitutes a dielectric liner 73 (i.e., sidewall spacers).

Optionally, the dielectric fill material portion 72 may embed an air gap 75 that is free of any solid phase material at the level(s) of the first drain-select-level electrode strips 461. The set of all structural elements that fills a respective drain-select-level isolation trench 71 constitutes a drain-select-level isolation structure (72, optionally 73 and/or 75). Thus, a drain-select-level isolation structure (72, optionally 73 and/or 75) can be formed in each drain-select-level isolation trench 71.

The drain-select-level isolation structure (72, optionally 73 and/or 75) can be formed between and in contact with a first row of memory opening fill structures 58 and a second row of memory opening fill structures 58. The drain-select-level isolation structure (72, optionally 73 and/or 75) vertically extends through a subset of layers within the alternating stack (32, 46) and laterally extends generally along the first horizontal direction hd1 with lateral undulations along the second horizontal direction hd2 such that a first electrically conductive layer 46A within the alternating stack (32, 46) is divided into a set of at least two first drain-select-level electrode strips 461. The drain-select-level isolation structure (72, optionally 73 and/or 75) laterally protrudes into each memory opening fill structure 58 in the first row and the second row and does not laterally protrude into the first drain-select-level electrode strips (i.e., SGD electrodes) 461 within gaps between neighboring pairs of the memory opening fill structures 58 that are laterally spaced along the first horizontal direction hd1 in the first row and the second row.

In one embodiment, each of the memory opening fill structures 58 comprises a respective dielectric core 62 that is laterally surrounded by the vertical semiconductor channel 60; and the drain-select-level isolation structure (72, optionally 73 and/or 75) is in contact with each dielectric core 62 within the first row and the second row. In one embodiment, for each memory opening fill structure 58, the respective vertical semiconductor channel 60 comprises an inner sidewall; and the drain-select-level isolation structure (72, optionally 73 and/or 75) is in contact with surface segments of the inner sidewall of the vertical semiconductor channel 60 of each memory opening fill structure 58 within the first row and the second row.

In one embodiment, the drain-select-level isolation structure (72, optionally 73 and/or 75) comprises horizontally-concave and vertically-straight surface segments that contact horizontally-convex and vertically-straight surface segments of the dielectric cores 62 within the first row and the second row.

In one embodiment, portions of the drain-select-level isolation structure (72, optionally 73 and/or 75) are located within a subset of the memory openings 49 that contains the first row of memory openings 49 and the second row of memory openings 49; and the portions of the drain-select-level isolation structure (72, optionally 73 and/or 75) are in contact with surface segments of sidewalls of the first drain-select-level electrode strips 461.

In one embodiment, portions of the drain-select-level isolation structure (72, optionally 73 and/or 75) located within gaps between the neighboring pairs of memory opening fill structures 58 that are laterally spaced along the first horizontal direction hd1 comprise straight sidewall segments that are parallel to the first horizontal direction hd1 and in contact with a respective one of the first drain-select-level electrode strips 461.

In one embodiment, the first electrically conductive layer 46A underlies a second electrically conductive layer 46B of the electrically conductive layers 46. The second electrically conductive layer 46B is more proximal to the drain regions 63 of the memory opening fill structures 58 than the first electrically conductive layer 46A is to the drain regions 63. The drain-select-level isolation structure (72, optionally 73 and/or 75) divides the second electrically conductive layer 46B into a pair of second drain-select-level electrode strips 462. In one embodiment, the drain-select-level isolation structure (72, optionally 73 and/or 75) is laterally wider at the vertical level of the first drain-select-level electrode strips 461 than the second drain-select-level electrode strips 462. In one embodiment, interfaces between the drain-select-level isolation structure (72, optionally 73 and/or 75) and the pair of second drain-select-level electrode strips 462 consists of planar surface segments that are parallel to the first horizontal direction hd1. In one embodiment, interfaces between the drain-select-level isolation structure (72, optionally 73 and/or 75) and the memory opening fill structures 58 in the first row and the second row consist of planar surface segments that are parallel to the first horizontal direction hd1.

In one embodiment, the drain-select-level isolation structure (72, optionally 73 and/or 75) comprises: a dielectric liner layer 73L in contact with the pair of second drain-select-level electrode strips 462 and not in contact with the pair of first drain-select-level electrode strips 461; and a dielectric fill material portion 72 comprising an upper portion that is laterally surrounded by the dielectric liner layer 73L and a lower portion that underlies the dielectric liner layer 73L and in contact with the pair of first drain-select-level electrode strips 461. In one embodiment, the upper portion of the dielectric fill material portion 72 has a lesser width along the second horizontal direction hd2 than the lower portion of the dielectric fill material portion 72; and the lower portion of the dielectric fill material portion 72 contains an air gap 75 that is free of any solid phase material therein.

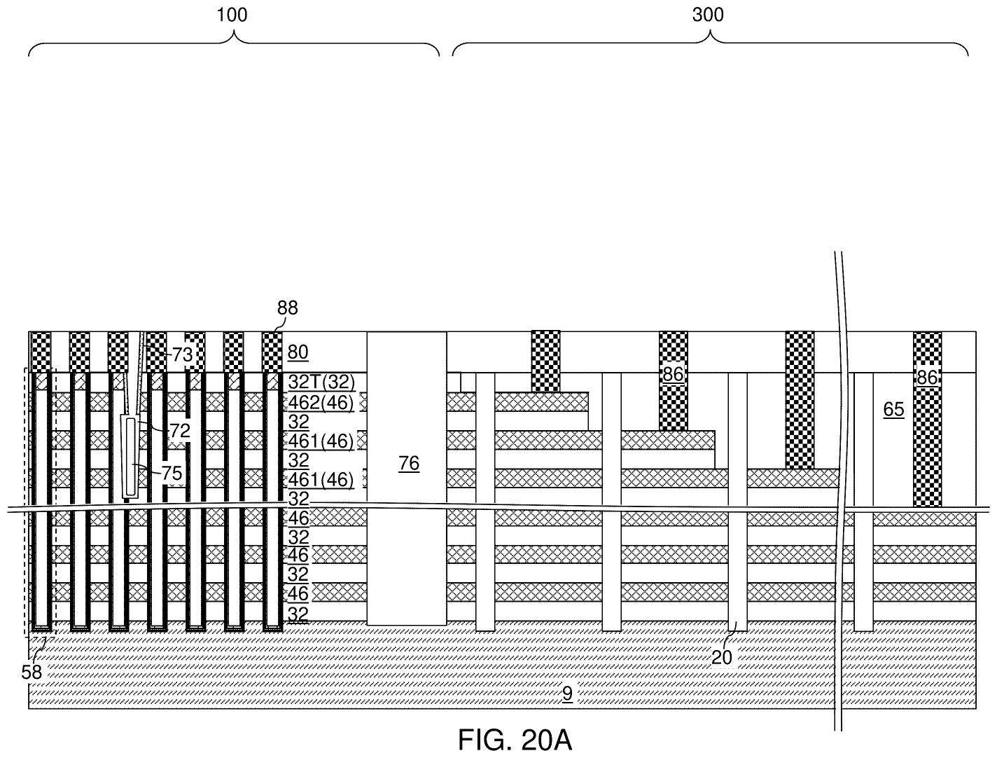

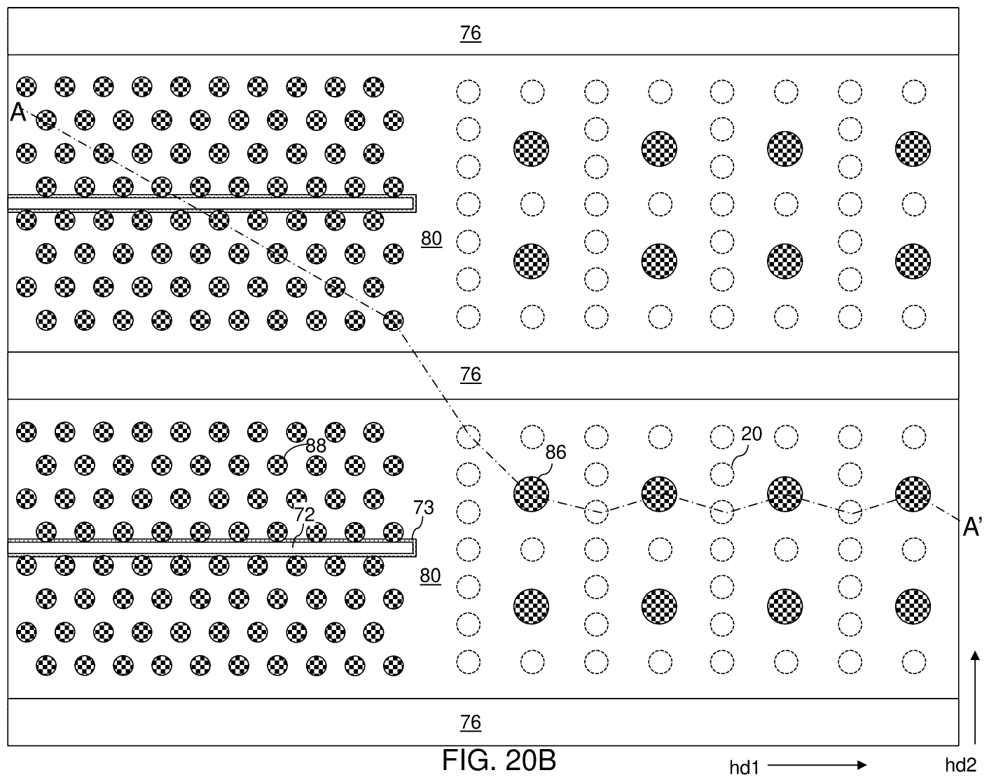

Referring to FIGS. 20A and 20B, contact via structures (88, 86) can be formed through the contact-level dielectric layer 80, and optionally through the stepped dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portion 65.

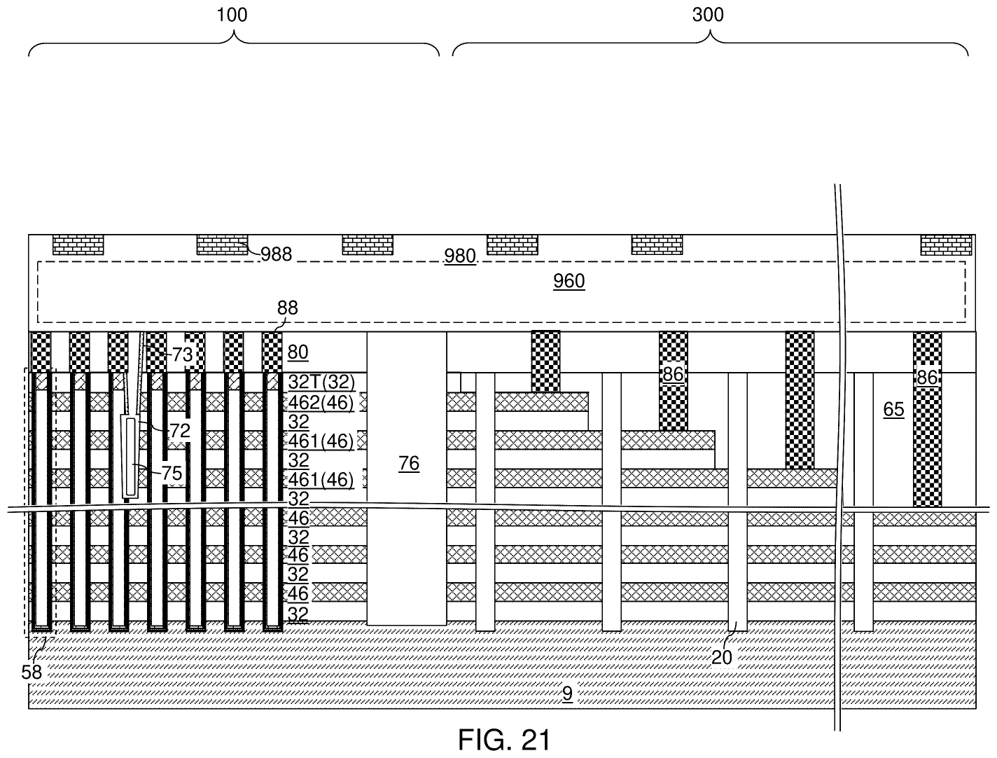

Referring to FIG. 21, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side metal interconnect structures 980. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

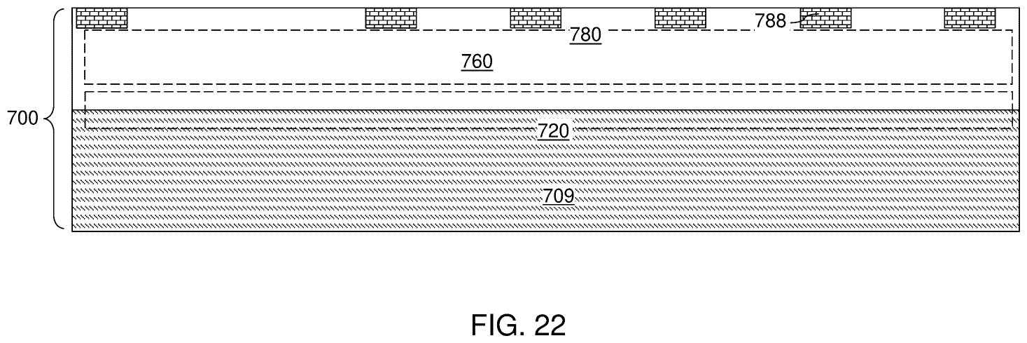

Referring to FIG. 22, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

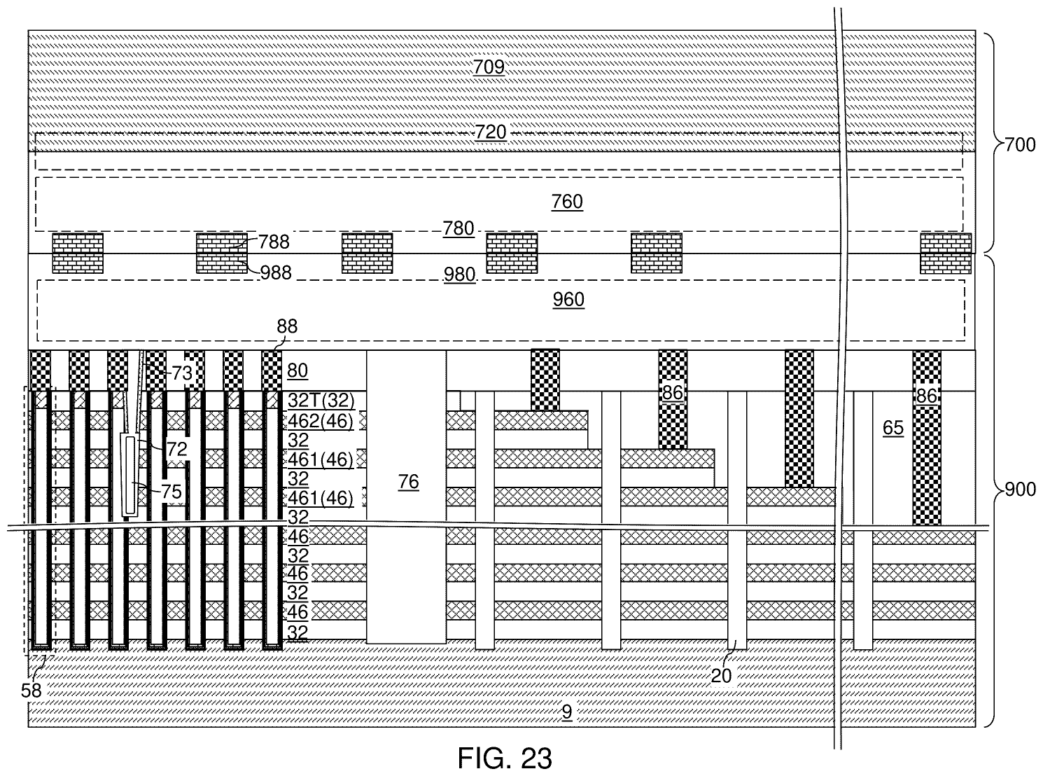

Referring to FIG. 23, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

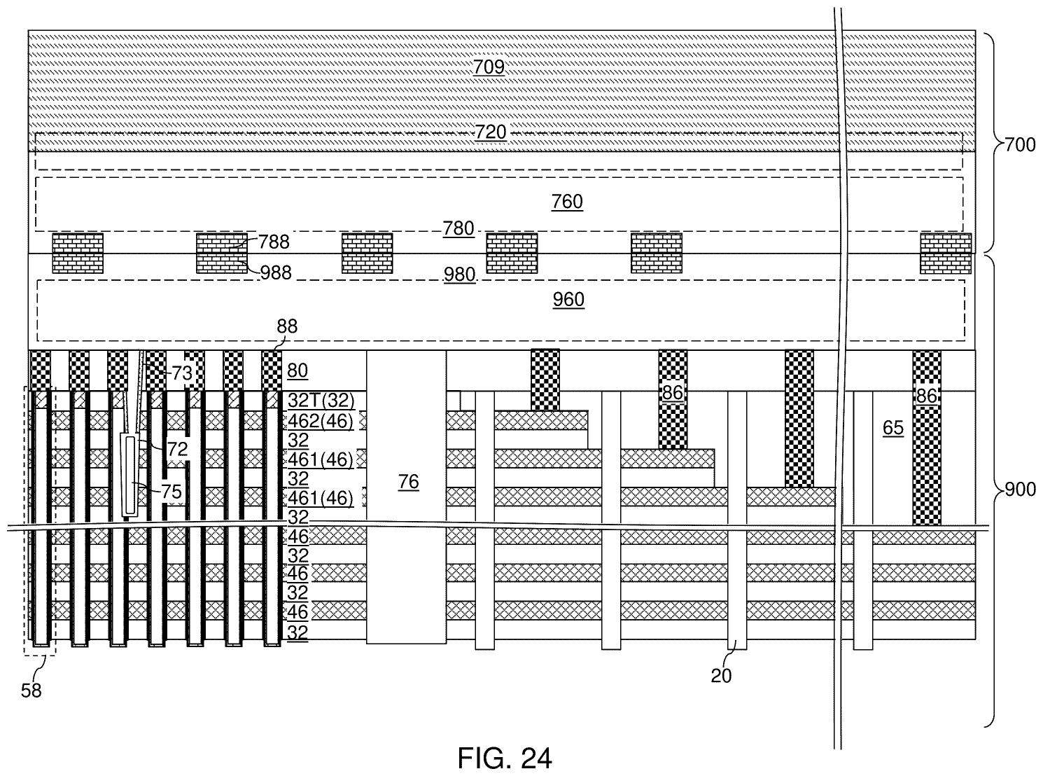

Referring to FIG. 24, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layer 32B may be employed as a polish stop or etch stop, respectively.

In one embodiment, at least a terminal step of at least one removal process that is employed to remove the carrier substrate 9 may comprise a selective wet etch process that etches the material of the carrier substrate 9 (such as a semiconductor material of the carrier substrate 9) selective to dielectric materials of the memory films 50. In an illustrative example, if the carrier substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the carrier substrate 9 can be removed by the selective wet etch process. Backside end surfaces of the support pillar structures 20 can be physically exposed upon removal of the carrier substrate 9.

A sequence of wet etch steps can be performed to sequentially remove portions of the memory film 50 that are exposed on the backside of the alternating stack (32, 46). For example, the inner blocking dielectric layer 52, the memory material layer 54, and the optional dielectric liner 56 (which may be, for example, a tunneling dielectric layer) of each memory film 50 can be removed from a region that is more distal from the bonding interface between the memory die 900 and the logic die 700 than a physically exposed planar surface of the bottommost insulating layer 32B is from the bonding interface. For the purpose of convenience, geometrical features of the exemplary structure and other exemplary structures in the present disclosure may be described in an orientation in which the logic die 700 overlies the memory die 900. Viewed in this orientation, the blocking dielectric layer 52, the memory material layer 54, and the optional dielectric liner 56 (which may be, for example, a tunneling dielectric layer) of each memory film 50 can be removed from below the horizontal plane including the bottom surface of the bottommost insulating layer 32B.

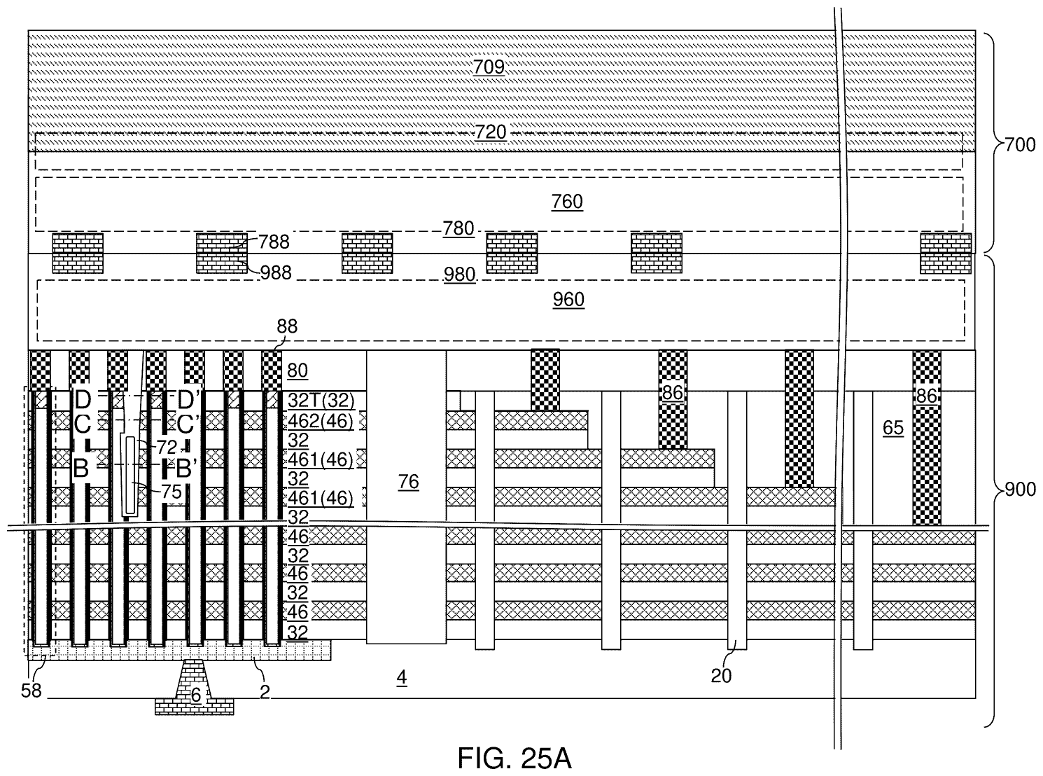

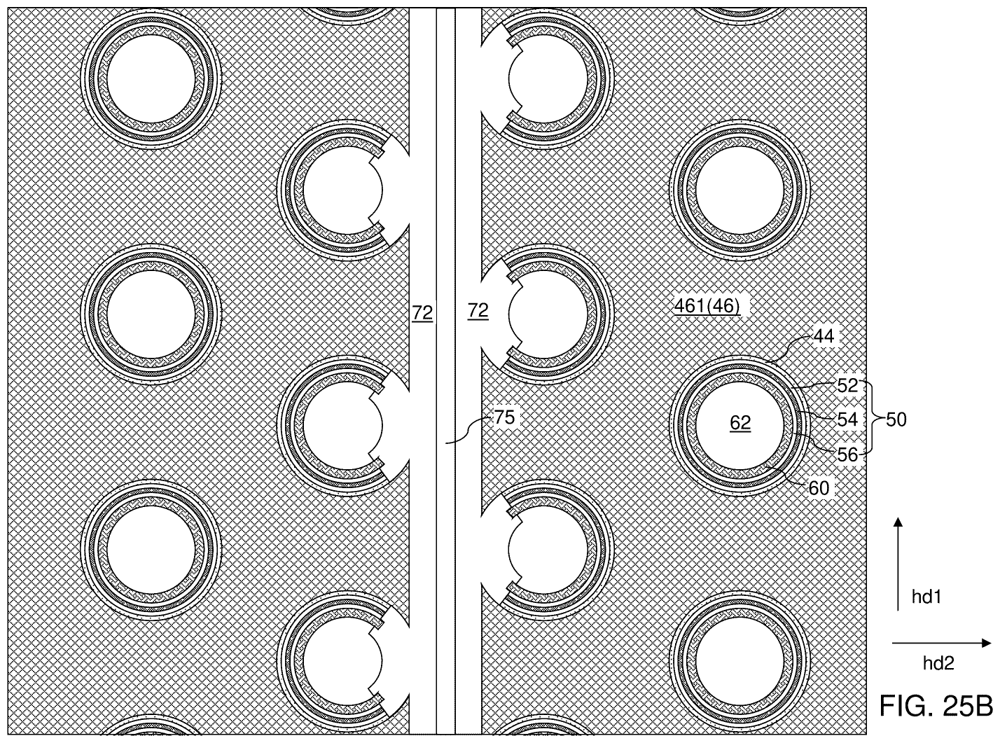

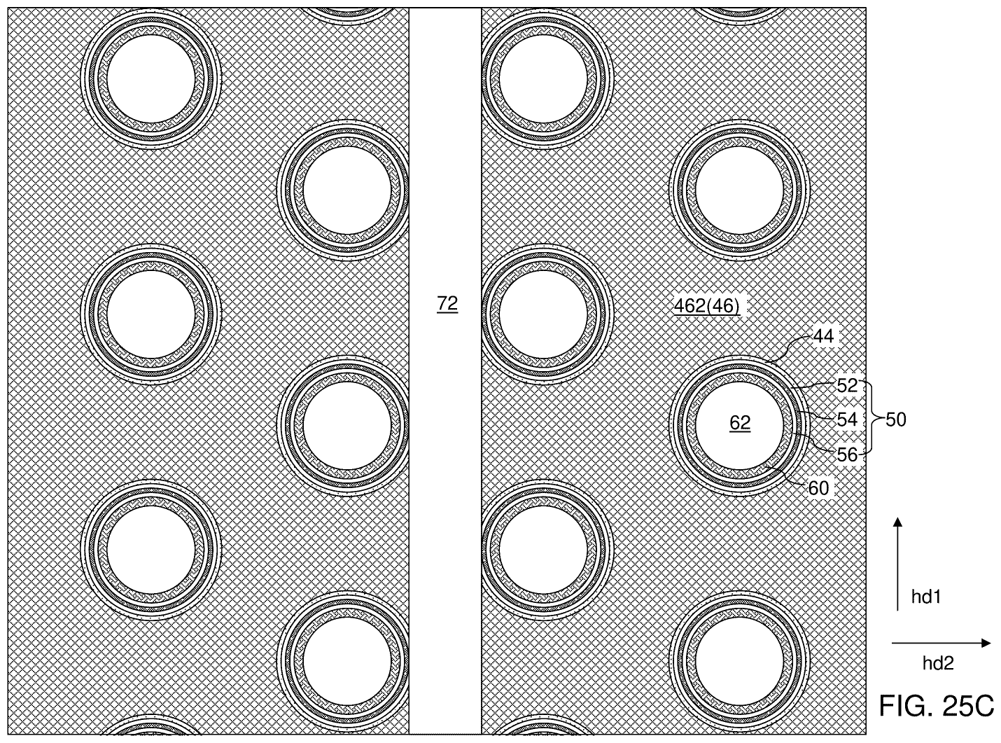

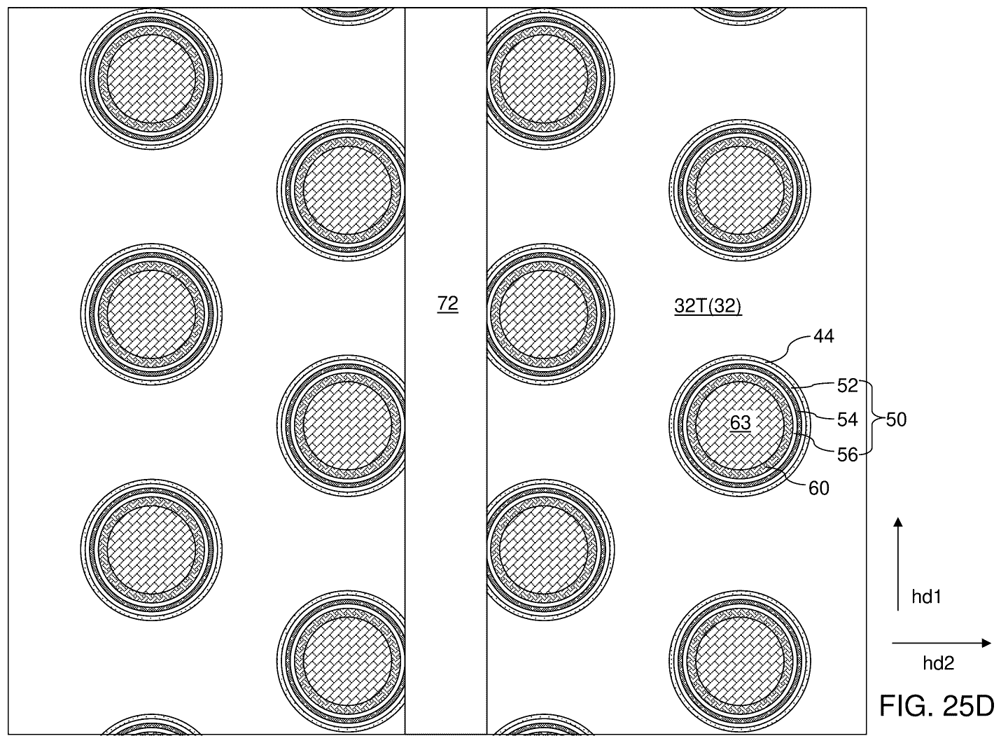

Referring to FIGS. 25A-25D, a source layer 2 may be formed in contact with the exposed ends of the vertical semiconductor channels 60 and the backside surface of the bottommost insulating layer 32B. The source layer 2 may comprise a doped semiconductor (e.g., polysilicon) layer and/or one or more metallic layers (e.g., TiN/W). A backside insulating layer 4 can be formed over the at least one source layer 2, and backside contact pad structures 6 can be formed through the backside insulating layer 4.

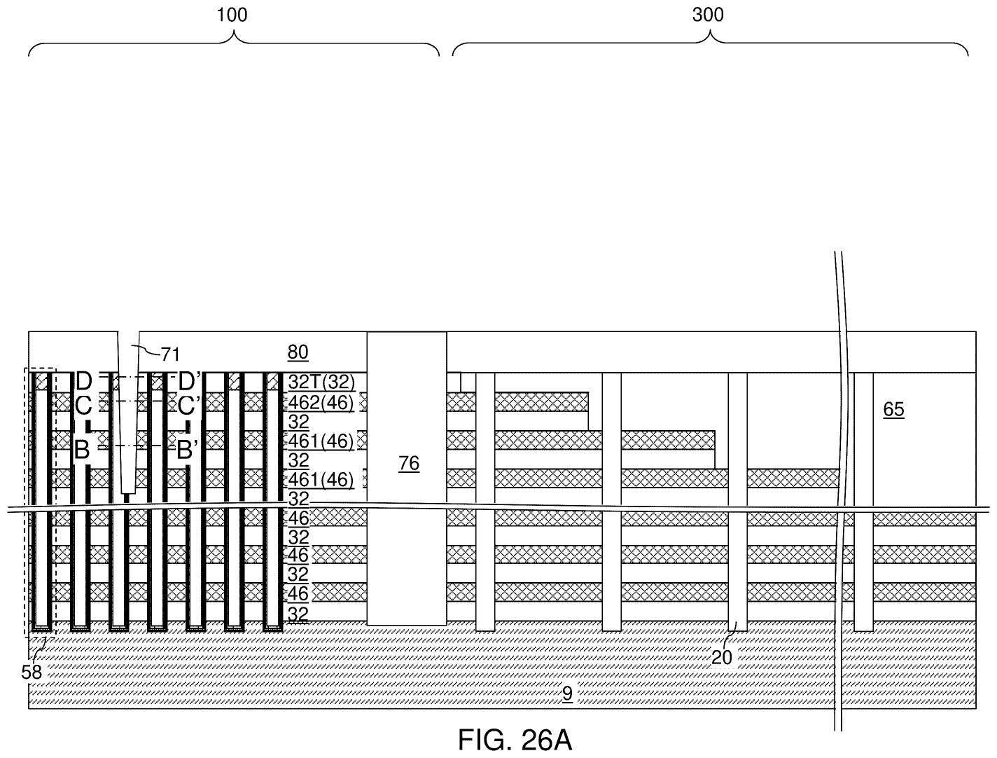

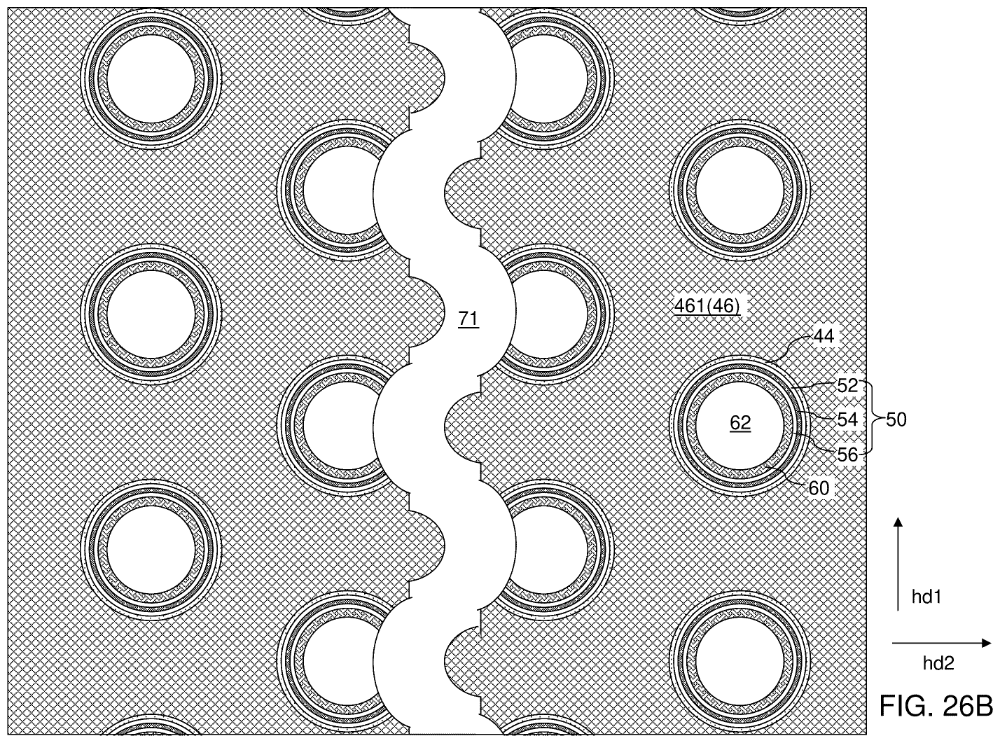

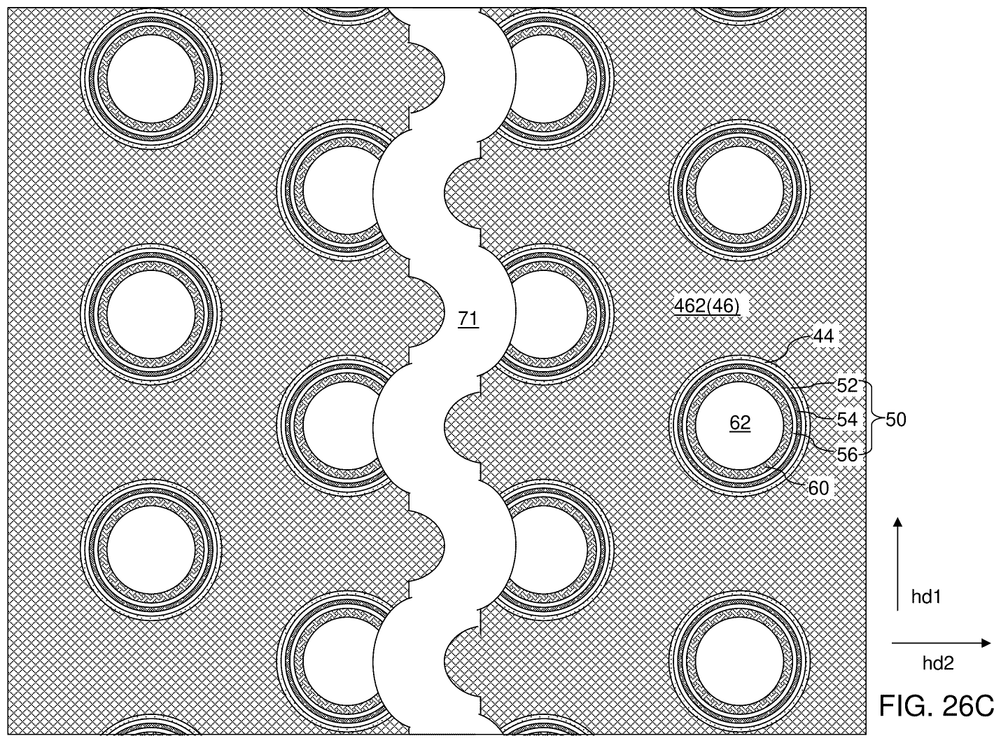

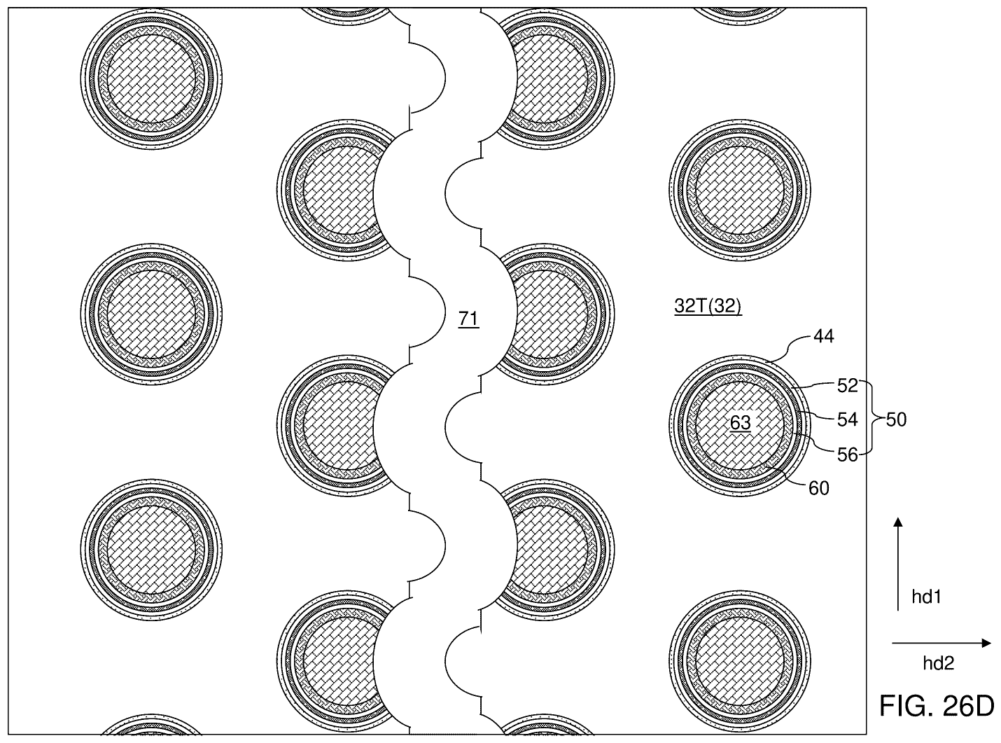

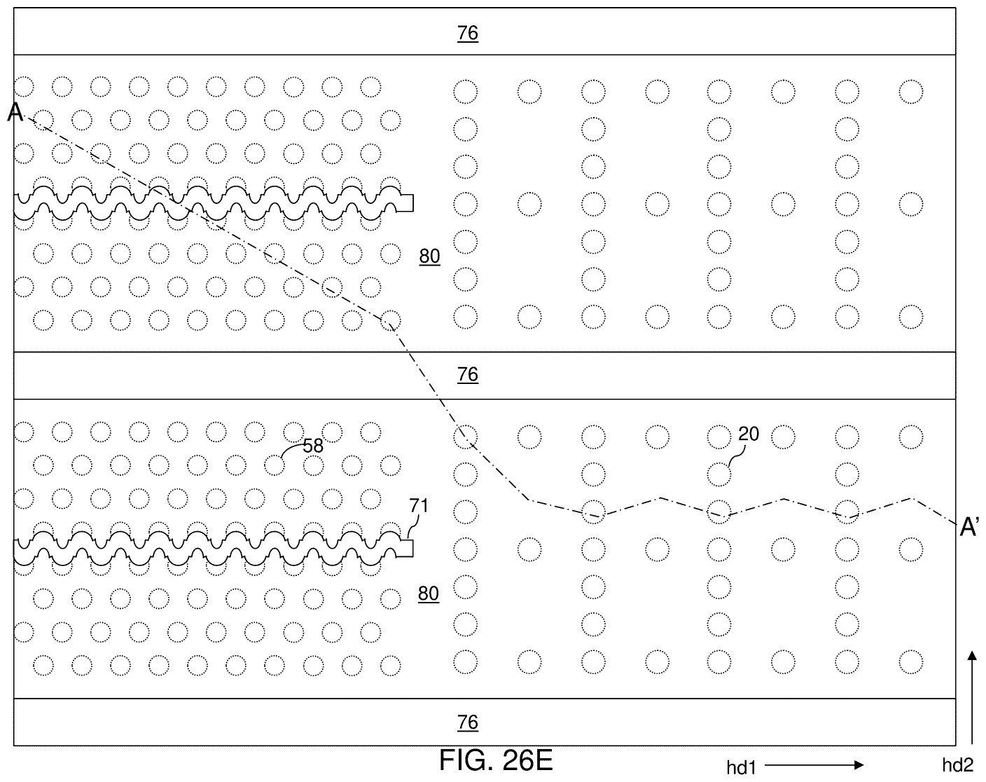

Referring to FIGS. 26A-26E, a second exemplary structure of the second embodiment can be derived from the first exemplary structure illustrated in FIG. 12 by forming drain-select-level isolation trenches 71 through the contact-level dielectric layer 80 and each of the at least one second electrically conductive layer 46B and the at least one first electrically conductive layer 46A and each insulating layer 32 that overlies the bottommost first electrically conductive layer 46A. A photoresist layer (not shown) can be applied over the contact-level dielectric layer 80, and can be lithographically patterned to form a pattern of discrete openings having a respective laterally-meandering line shape, and an anisotropic etch process can be performed to transfer the pattern of the discrete openings through the contact-level dielectric layer 80 and each of the at least one second electrically conductive layer 46B and the at least one first electrically conductive layer 46A and each insulating layer 32 that overlies the bottommost first electrically conductive layer 46A. The photoresist layer can be subsequently removed.

Each of the drain-select-level isolation trenches 71 may have a horizontal cross-sectional shape of a meandering line that generally extends along the first horizontal direction hd1 with lateral protrusions along the second horizontal direction hd2. Each drain-select-level isolation trench 71 can be formed between a respective first row of memory opening fill structures 58 and a respective neighboring second row of memory opening fill structures 58.

According to an aspect of the present disclosure, the lateral undulation pattern of the horizontal cross-sectional shape of the drain-select-level isolation trench 71 may have the same pitch as the pitch of each row of memory opening fill structures 58 along the first horizontal direction hd1. Further, the locations of maximum lateral protrusion of each undulation may be at a respective one of the memory opening fill structures 58 such that each lateral protrusion of the horizontal cross-sectional shape of the drain-select-level isolation trench 71 cuts through an edge portion of a respective one of the memory opening fill structures 58. Formation of damaged and/or ungated portions of the outer blocking dielectric layers 44 can be avoided or minimized to avoid or minimize the electron de-trapping.

Portions of the drain-select-level isolation trench 71 located within gaps between neighboring pairs of memory opening fill structures 58 (which are laterally spaced along the first horizontal direction hd1) within a row of memory opening fill structures 58 comprise lateral recess regions in which the drain-select-level isolation trench 71 is laterally recessed away from row of memory opening fill structures 58 along the second horizontal direction hd1. Portions of the first drain-select-level electrode strips 461 and portions of the second drain-select-level electrode strips 462 laterally protrude into the lateral recess regions.

In one embodiment, the drain-select-level isolation trench 71 may cut through portions of the dielectric cores 62 within a neighboring pair of rows of memory opening fill structures. In one embodiment, each of the memory opening fill structures 58 comprises a respective dielectric core 62 that is laterally surrounded by the vertical semiconductor channel 60. Laterally-convex and vertically-straight surface segments of the dielectric cores 62 within the neighboring pair of rows of memory opening fill structures 58 can be exposed to the drain-select-level isolation trench 71.

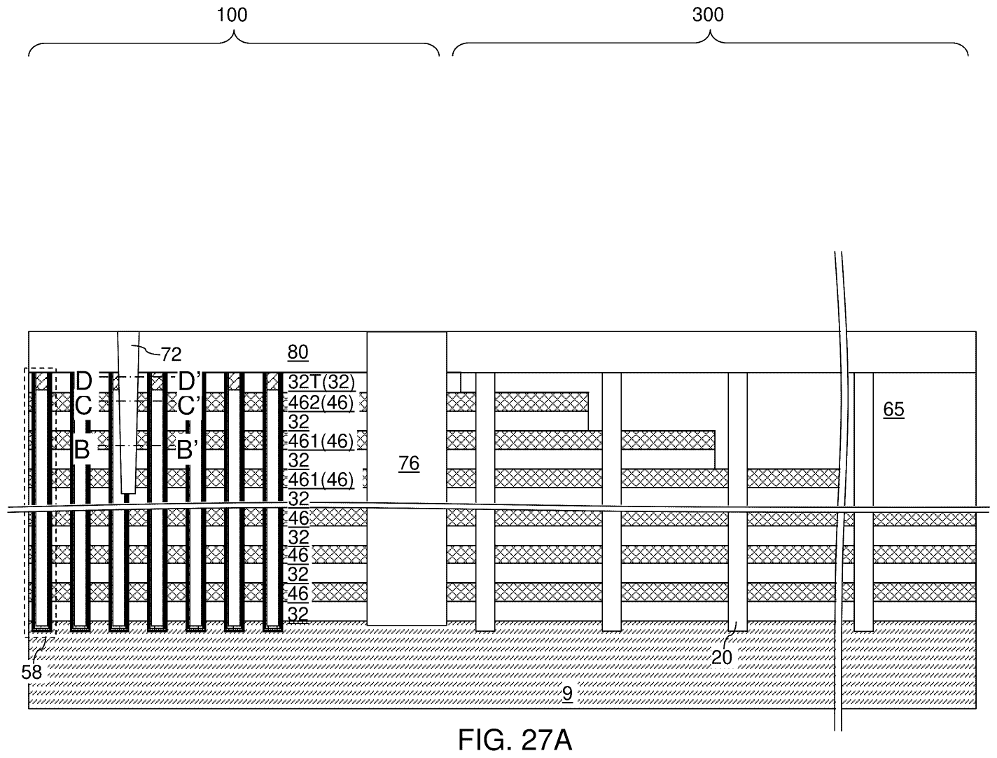

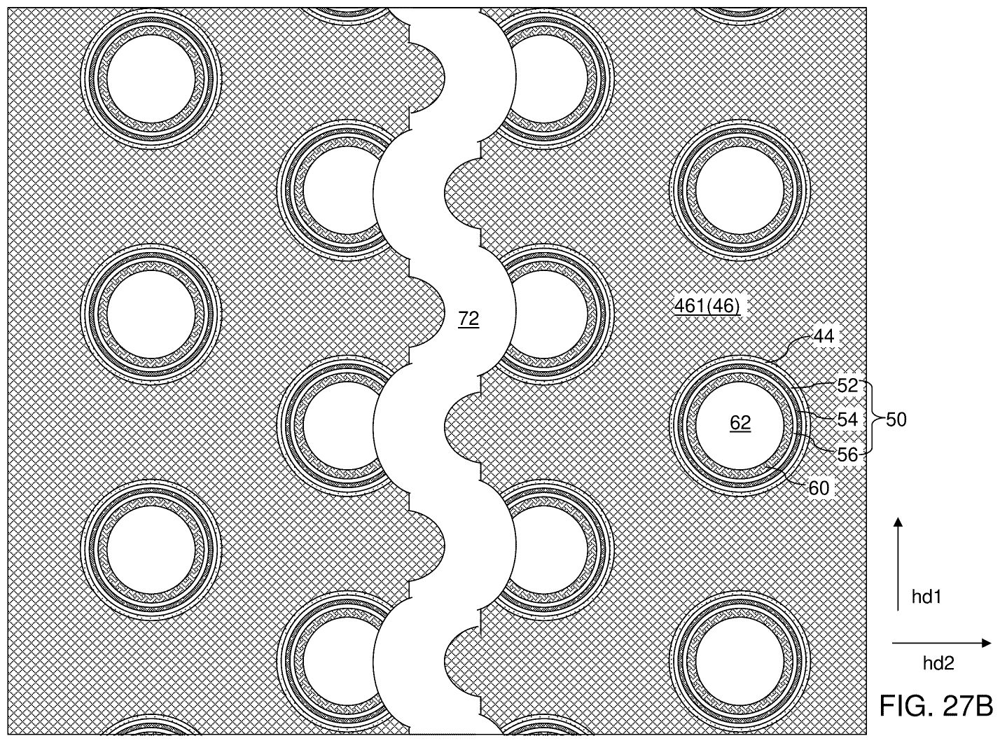

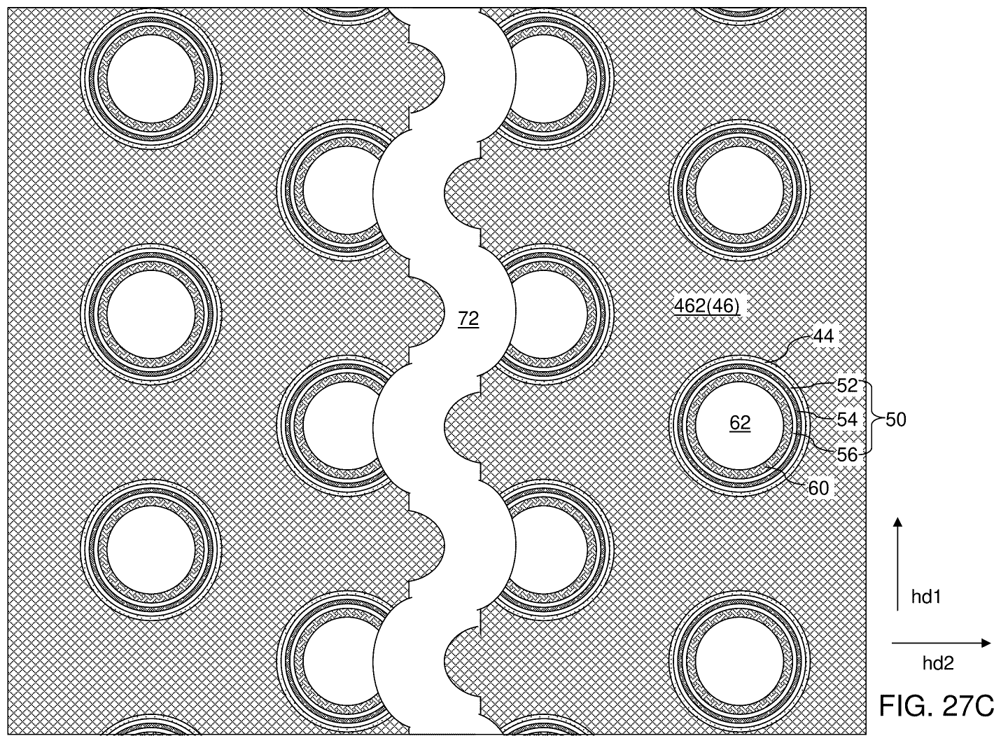

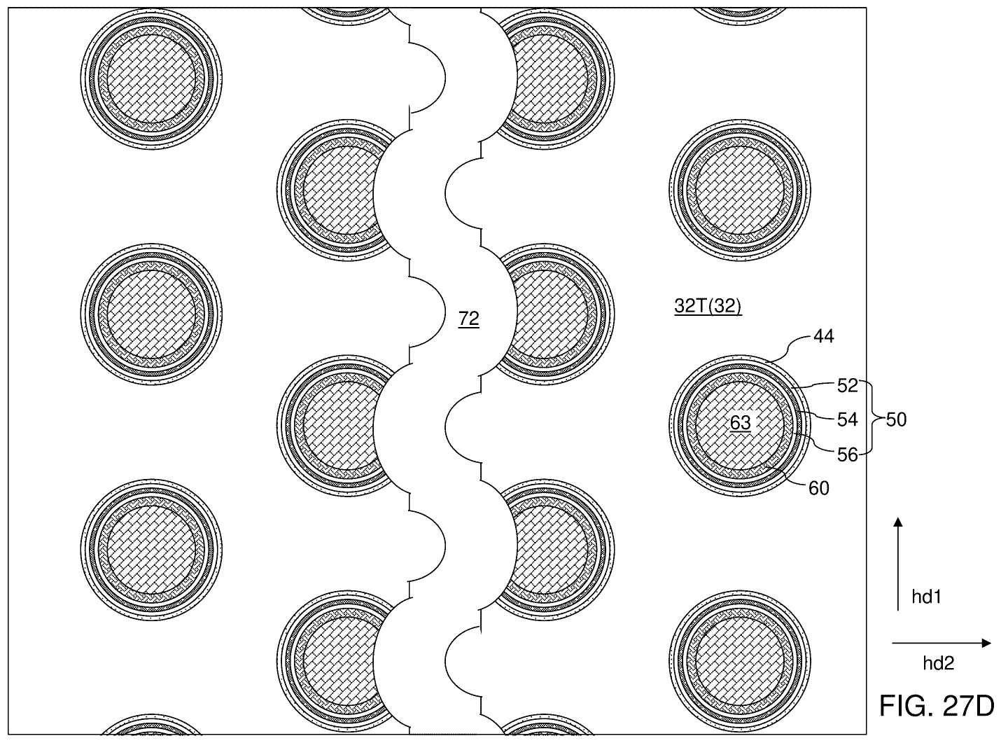

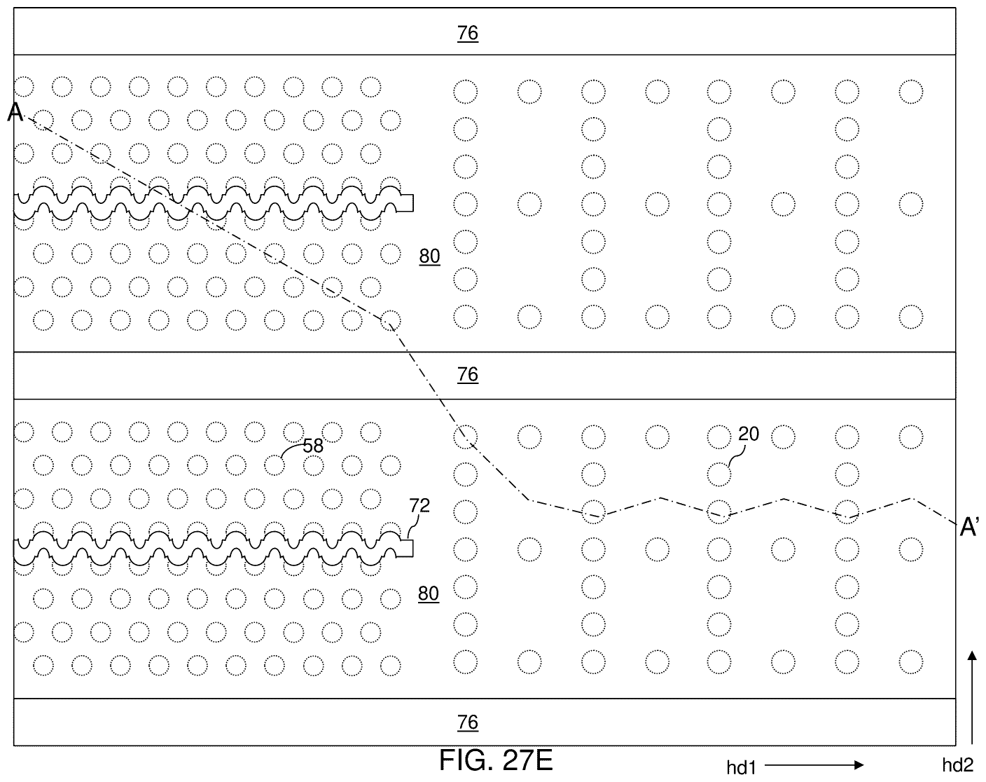

Referring to FIGS. 27A-27E, a dielectric fill material, such as undoped silicate glass or a doped silicate glass, can be deposited in the drain-select-level isolation trenches 71. Portions of the dielectric fill material that overlies the horizontal plane including the top surface of the contact-level dielectric layer 80 can be removed by performing a planarization process such as a chemical mechanical polishing process. Each remaining portion of the dielectric fill material that fills a respective one of the drain-select-level isolation trenches 71 constitutes the drain-select-level isolation structure 72 which consists essentially of a dielectric fill material portion.

The drain-select-level isolation structures 72 vertically extend through a subset of layers within the alternating stack (32, 46) and laterally extend generally along the first horizontal direction hd1 with lateral undulations along the second horizontal direction hd2. Each first electrically conductive layer 46A within the alternating stack (32, 46) is divided into a respective set of at least two first drain-select-level electrode strips 461, and each second electrically conductive layer 46B within the alternating stack (32, 46) is divided into a respective set of at least two second drain-select-level electrode strips 462. Each drain-select-level isolation structure 72 is in contact with and is located between a respective first row of memory opening fill structures 58 and a respective second row of memory opening fill structures 58. In this embodiment, the drain-select-level isolation structure 72 has substantially the same lateral thickness at the levels of the first and the second drain-select-level electrode strips.

In the second exemplary structure, portions of the drain-select-level isolation structure 72 located within gaps between the neighboring pairs of memory opening fill structures 58 (which are laterally spaced along the first horizontal direction hd1) comprise lateral recess regions having horizontally-concave surface segments. Portions of the first drain-select-level electrode strips 461 laterally protrude into the lateral recess regions.

In one embodiment, each lengthwise sidewall of the drain-select-level isolation structure 72 in the second exemplary structure comprises a laterally alternating sequence of laterally-convex and vertically-straight surface segments that contact a respective one of the memory opening fill structures 58 in the first row and the second row and laterally-concave and vertically-straight surface segments that contact a respective laterally-convex and vertically-straight surface segment of the first drain-select-level electrode strips 461.

In one embodiment, each of the memory opening fill structures 58 comprises a respective dielectric core 62 that is laterally surrounded by the vertical semiconductor channel 60; and laterally-convex and vertically-straight surface segments of the drain-select-level isolation structure 72 are in contact with laterally-convex and vertically-straight surface segments of the dielectric cores 62 within the first row and the second row.

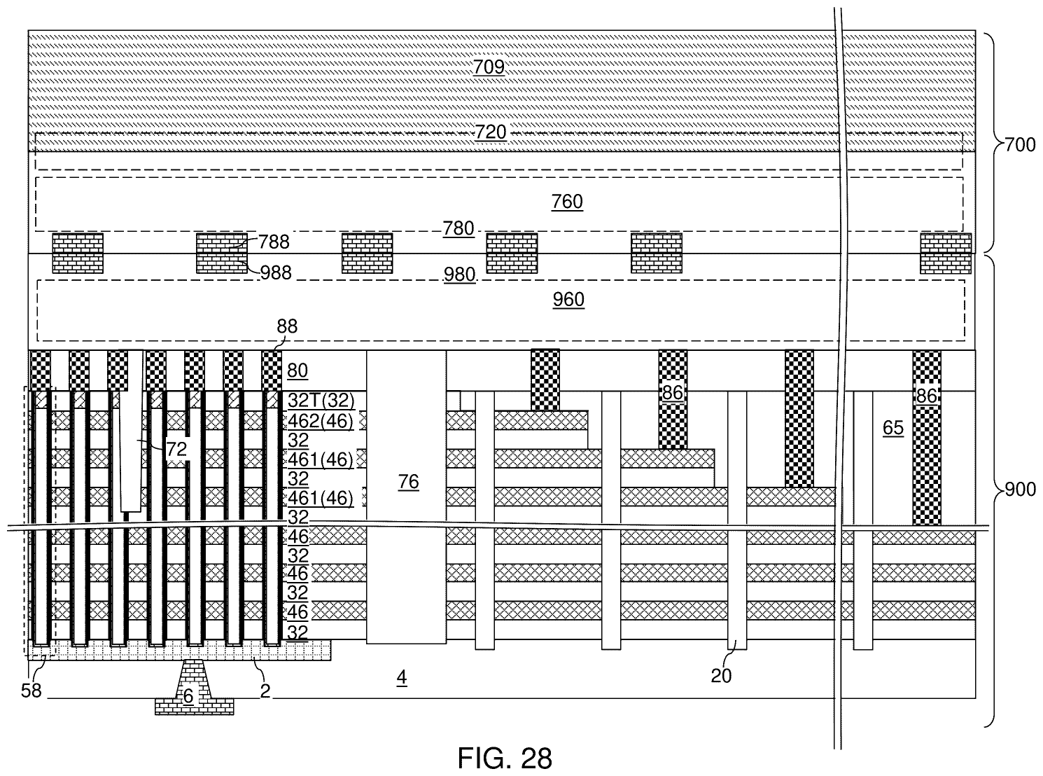

Referring to FIG. 28, the processing steps described with reference to FIGS. 20A-25D can be performed on the second exemplary structure.

Referring to all drawings and according to various embodiments of the present disclosure, a three-dimensional memory device comprises: an alternating stack (32, 46) of insulating layers 32 and electrically conductive layers 46; memory openings 49 vertically extending through the alternating stack (32, 46); memory opening fill structures 58 located in the memory openings 49, wherein each of the memory opening fill structures 58 comprises a respective vertical semiconductor channel 60, a respective vertical stack of memory elements (as embodied as portions of a memory film 50 located at levels of the electrically conductive layers 46), and a respective drain region 63, wherein the memory opening fill structures 58 are arranged in rows laterally extending along a first horizontal direction hd1, and the rows are laterally spaced apart from each other along a second horizontal direction hd2 that is perpendicular to the first horizontal direction hd1; and a drain-select-level isolation structure (72, optionally 73 and/or 75) vertically extending through a subset of the electrically conductive layers (e.g., 46A, 46B) within the alternating stack (32, 46) and laterally extending generally along the first horizontal direction hd1 with lateral undulations along the second horizontal direction hd2 such that a first electrically conductive layer 46A within the alternating stack (32, 46) is divided into a set of at least two first drain-select-level electrode strips 461. The drain-select-level isolation structure (72, optionally 73 and/or 75) is in contact with, and is located between, a first row of memory opening fill structures 58 and a second row of memory opening fill structures 58; and the drain-select-level isolation structure (72, optionally 73 and/or 75) laterally protrudes into each memory opening fill structure 58 in the first row and the second row and does not laterally protrude into the first drain-select-level electrode strips 461 within gaps between neighboring pairs of the memory opening fill structures 58 that are laterally spaced along the first horizontal direction hd1 in the first row and the second row.

In one embodiment, each of the memory opening fill structures 58 also comprises a respective dielectric core 62 that is laterally surrounded by the vertical semiconductor channel 60; and the drain-select-level isolation structure (72, optionally 73 and/or 75) is in contact with each dielectric core 62 within the first row and the second row. In one embodiment, for each memory opening fill structure 58, the respective vertical semiconductor channel 60 comprises an inner sidewall; and the drain-select-level isolation structure (72, optionally 73 and/or 75) is in contact with surface segments of the inner sidewall of the vertical semiconductor channel 60 of each memory opening fill structure 58 within the first row and the second row. In one embodiment, the drain-select-level isolation structure (72, optionally 73 and/or 75) comprises horizontally-concave and vertically-straight surface segments that contact horizontally-convex and vertically-straight surface segments of the dielectric cores 62 within the first row and the second row.

In one embodiment, portions of the drain-select-level isolation structure (72, optionally 73 and/or 75) are located within a subset of the memory openings 49 that contains the first row of memory openings 49 and the second row of memory openings 49; and the portions of the drain-select-level isolation structure (72, optionally 73 and/or 75) are in contact with surface segments of sidewalls of the first drain-select-level electrode strips 461.

In one embodiment, portions of the drain-select-level isolation structure (72, optionally 73 and/or 75) located within gaps between the neighboring pairs of memory opening fill structures 58 that are laterally spaced along the first horizontal direction hd1 comprise straight sidewall segments that are parallel to the first horizontal direction hd1 and in contact with a respective one of the first drain-select-level electrode strips 461.

In one embodiment, the first electrically conductive layer 46A underlies a second electrically conductive layer 46B of the electrically conductive layers 46, wherein the second electrically conductive layer 46B is more proximal to the drain regions 63 of the memory opening fill structures 58 than the first electrically conductive layer 46A is to the drain regions 63; and the drain-select-level isolation structure (72, optionally 73 and/or 75) divides the second electrically conductive layer 46B into a pair of second drain-select-level electrode strips 462. In one embodiment, the drain-select-level isolation structure is wider at a vertical level of the first drain-select-level electrode strips 461 than at a vertical level of the second drain-select-level electrode strips 462.

In one embodiment, interfaces between the drain-select-level isolation structure (72, optionally 73 and/or 75) and the pair of second drain-select-level electrode strips 462 comprise planar surface segments that are parallel the first horizontal direction hd1. In one embodiment, interfaces between the drain-select-level isolation structure (72, optionally 73 and/or 75) and the memory opening fill structures 58 in the first row and the second row comprise planar surface segments that are parallel to the first horizontal direction hd1.

In one embodiment, the drain-select-level isolation structure (72, optionally 73 and/or 75) comprises: a dielectric liner layer 73L in contact with the pair of second drain-select-level electrode strips 462 and not in contact with the pair of first drain-select-level electrode strips 461; and a dielectric fill material portion 72 comprising an upper portion that is laterally surrounded by the dielectric liner layer 73L and a lower portion that underlies the dielectric liner layer 73L and in contact with the pair of first drain-select-level electrode strips 461. In one embodiment, the upper portion of the dielectric fill material portion 72 has a lesser width along the second horizontal direction hd2 than the lower portion of the dielectric fill material portion 72; and the lower portion of the dielectric fill material portion 72 contains an air gap 75.

In one embodiment, portions of the drain-select-level isolation structure 72 located within gaps between the neighboring pairs of memory opening fill structures 58 that are laterally spaced along the first horizontal direction hd1 comprise lateral recess regions having horizontally-concave surface segments, wherein portions of the first drain-select-level electrode strips 461 laterally protrude into the lateral recess regions. In one embodiment, each lengthwise sidewall of the drain-select-level isolation structure 72 comprises a laterally alternating sequence of laterally-convex and vertically-straight surface segments that contact a respective one of the memory opening fill structures 58 in the first row and the second row and laterally-concave and vertically-straight surface segments that contact a respective laterally-convex and vertically-straight surface segment of the first drain-select-level electrode strips 461.

In one embodiment, each of the memory opening fill structures 58 further comprises a memory film 50 comprising an inner blocking dielectric layer 52, a tunneling dielectric layer 56 and a memory material layer 54 comprising the vertical stack of memory elements and located between the inner blocking dielectric layer and the tunneling dielectric layer. An outer blocking dielectric layer 44 having a convex outer surface is located between the memory film 50 and the first drain-select-level electrode strips 461. The entire convex outer surface of the outer blocking dielectric layer 44 at a vertical level of the first drain-select-level electrode strips is contacted by the first drain-select-level electrode strips 461, and the convex outer surface of the outer blocking dielectric layer 44 does not contact the drain-select-level isolation structure (72, optionally 73 and/or 75). Thus, the ungated portions of the outer blocking dielectric layer 44 are eliminated.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A three-dimensional memory device, comprising:
an alternating stack of insulating layers and electrically conductive layers;
memory openings vertically extending through the alternating stack;
memory opening fill structures located in the memory openings, wherein each of the memory opening fill structures comprises a respective vertical semiconductor channel, a respective vertical stack of memory elements, and a respective drain region, wherein the memory opening fill structures are arranged in rows laterally extending along a first horizontal direction, and the rows are laterally spaced apart from each other along a second horizontal direction that is perpendicular to the first horizontal direction; and
a drain-select-level isolation structure vertically extending through a subset of the electrically conductive layers within the alternating stack and laterally extending generally along the first horizontal direction with lateral undulations along the second horizontal direction such that a first electrically conductive layer within the alternating stack is divided into a set of at least two first drain-select-level electrode strips,
wherein:
the drain-select-level isolation structure is in contact with and is located between a first row of memory opening fill structures and a second row of memory opening fill structures; and
the drain-select-level isolation structure laterally protrudes into each memory opening fill structure in the first row and the second row and does not laterally protrude into the first drain-select-level electrode strips within gaps between neighboring pairs of the memory opening fill structures that are laterally spaced along the first horizontal direction in the first row and the second row.

2. The three-dimensional memory device of claim 1, wherein:
each of the memory opening fill structures further comprises a respective dielectric core that is laterally surrounded by the vertical semiconductor channel; and
the drain-select-level isolation structure is in contact with each dielectric core within the first row and the second row.

3. The three-dimensional memory device of claim 2, wherein:
for each memory opening fill structure, the respective vertical semiconductor channel comprises an inner sidewall; and
the drain-select-level isolation structure is in contact with surface segments of the inner sidewall of the vertical semiconductor channel of each memory opening fill structure within the first row and the second row.

4. The three-dimensional memory device of claim 2, wherein the drain-select-level isolation structure comprises horizontally-concave and vertically-straight surface segments that contact horizontally-convex and vertically-straight surface segments of the dielectric cores within the first row and the second row.

5. The three-dimensional memory device of claim 1, wherein:
portions of the drain-select-level isolation structure are located within a subset of the memory openings that contains the first row of memory openings and the second row of memory openings; and
the portions of the drain-select-level isolation structure are in contact with surface segments of sidewalls of the first drain-select-level electrode strips.

6. The three-dimensional memory device of claim 1, wherein portions of the drain-select-level isolation structure located within gaps between the neighboring pairs of memory opening fill structures that are laterally spaced along the first horizontal direction comprise straight sidewall segments that are parallel to the first horizontal direction and in contact with a respective one of the first drain-select-level electrode strips.

7. The three-dimensional memory device of claim 1, wherein:
the first electrically conductive layer underlies a second electrically conductive layer of the electrically conductive layers, wherein the second electrically conductive layer is more proximal to the drain regions of the memory opening fill structures than the first electrically conductive layer is to the drain regions; and
the drain-select-level isolation structure divides the second electrically conductive layer into a pair of second drain-select-level electrode strips.

8. The three-dimensional memory device of claim 7, wherein the drain-select-level isolation structure is wider at a vertical level of the first drain-select-level electrode strips than at a vertical level of the second drain-select-level electrode strips.

9. The three-dimensional memory device of claim 7, wherein:
interfaces between the drain-select-level isolation structure and the pair of second drain-select-level electrode strips comprise planar surface segments that are parallel the first horizontal direction; and
interfaces between the drain-select-level isolation structure and the memory opening fill structures in the first row and the second row comprise planar surface segments that are parallel to the first horizontal direction.

10. The three-dimensional memory device of claim 7, wherein the drain-select-level isolation structure comprises:
a dielectric liner in contact with the pair of second drain-select-level electrode strips and not in contact with the pair of first drain-select-level electrode strips; and
a dielectric fill material portion comprising an upper portion that is laterally surrounded by the dielectric liner and a lower portion that underlies the dielectric liner and in contact with the pair of first drain-select-level electrode strips.

11. The three-dimensional memory device of claim 10, wherein:
the upper portion of the dielectric fill material portion has a lesser width along the second horizontal direction than the lower portion of the dielectric fill material portion; and
the lower portion of the dielectric fill material portion contains an air gap.

12. The three-dimensional memory device of claim 1, wherein portions of the drain-select-level isolation structure located within gaps between the neighboring pairs of memory opening fill structures that are laterally spaced along the first horizontal direction comprise lateral recess regions having horizontally-concave surface segments, wherein portions of the first drain-select-level electrode strips laterally protrude into the lateral recess regions.

13. The three-dimensional memory device of claim 12, wherein each lengthwise sidewall of the drain-select-level isolation structure comprises a laterally alternating sequence of laterally-convex and vertically-straight surface segments that contact a respective one of the memory opening fill structures in the first row and the second row and laterally-concave and vertically-straight surface segments that contact a respective laterally-convex and vertically-straight surface segment of the first drain-select-level electrode strips.

14. The three-dimensional memory device of claim 1, wherein:
each of the memory opening fill structures further comprises a memory film comprising an inner blocking dielectric layer, a tunneling dielectric layer and a memory material layer comprising the vertical stack of memory elements and located between the inner blocking dielectric layer and the tunneling dielectric layer;
an outer blocking dielectric layer having a convex outer surface is located between the memory film and the first drain-select-level electrode strips;
the entire convex outer surface of the outer blocking dielectric layer at a vertical level of the first drain-select-level electrode strips is contacted by the first drain-select-level electrode strips; and
the convex outer surface of the outer blocking dielectric layer does not contact the drain-select-level isolation structure.

15. A method of forming a semiconductor structure, comprising:
forming an alternating stack of insulating layers and spacer material layers over a substrate, wherein the spacer material layers are formed as or are subsequently replaced with electrically conductive layers;
forming memory openings through the alternating stack;
forming memory opening fill structures in the memory openings, wherein each of the memory opening fill structures comprises a respective memory film and a respective vertical semiconductor channel that is laterally surrounded by the respective memory film, wherein the memory opening fill structures are arranged in rows laterally extending along a first horizontal direction, and the rows are laterally spaced apart from each other along a second horizontal direction that is perpendicular to the first horizontal direction;
forming a drain-select-level isolation trench through a subset of electrically conductive layers including a first electrically conductive layer such that the drain-select-level isolation trench divides the first electrically conductive layer into a pair of first drain-select-level electrode strips and includes volumes formed by removal of portions of a first row of memory opening fill structures and a second row of memory opening fill structures; and
forming a drain-select-level isolation structure in the drain-select-level isolation trench, wherein the drain-select-level isolation structure laterally protrudes into each memory opening fill structure in the first row and the second row and does not laterally protrude into the first drain-select-level electrode strips within gaps between neighboring pairs of the memory opening fill structures that are laterally spaced along the first horizontal direction in the first row and the second row.

16. The method of claim 15, wherein the drain-select-level isolation trench is formed by:
performing an anisotropic etch process that etches a material of the first electrically conductive layer and a material of the insulating layers with a line cavity pattern having a pair of straight sidewalls that laterally extend along the first horizontal direction; and
performing an isotropic etch process that etches materials of the memory opening fill structures selective to the material of the first electrically conductive layer.

17. The method of claim 16, wherein the isotropic etch process comprises:
an etch step that etches portions of the memory films in the first row and the second row that are exposed to the line cavity pattern; and
another etch step that etches portions of the vertical semiconductor channels to a volume of a cavity that is formed by expansion of the line cavity pattern.

18. The method of claim 16, wherein:
the alternating stack comprises a second electrically conductive layer that overlies the first electrically conductive layer; and
the method further comprises forming an in-process drain-select-level isolation trench that vertically extends through the second electrically conductive layer by performing an additional anisotropic etch process, forming a dielectric liner in a peripheral portion of the in-process drain-select-level isolation trench, and by vertically extending the in-process drain-select-level isolation trench through the first electrically conductive layer by performing the anisotropic etch process.

19. The method of claim 15, wherein:
each of the memory opening fill structures further comprises a respective dielectric core that is laterally surrounded by the respective vertical semiconductor channel; and
the drain-select-level isolation structure comprises horizontally-concave and vertically-straight surface segments that are formed directly on horizontally-convex and vertically-straight surface segments of the dielectric cores within the first row and the second row.

20. The method of claim 15, wherein portions of the drain-select-level isolation structure located within gaps between the neighboring pairs of memory opening fill structures that are laterally spaced along the first horizontal direction comprise lateral recess regions having horizontally-concave surface segments, wherein portions of the first drain-select-level electrode strips laterally protrude into the lateral recess regions.
